(19) United States
(12) Patent Application Publication
(10) Pub. No.: US 2026/0136783 A1
(43) Pub. Date: May 14, 2026

(54) Display Substrate, Preparation Method Therefor, and Display Apparatus

(71) Applicants: Hefei BOE Joint Technology Co.,Ltd., Hefei, Anhui (CN); BOE Technology Group Co., Ltd., Beijing (CN)

(72) Inventors: Xiuting LIU, Beijing (CN); Zhidong YUAN, Beijing (CN); Yongqian LI, Beijing (CN)

(21) Appl. No.: 18/705,532

(22) PCT Filed: Apr. 28, 2023
(86) PCT No.: PCT/CN2023/091560

§ 371 Date: Apr. 27, 2024

(51) Int. Cl. H10K 59/131; H10K 59/12; H10K 59/121

(52) U.S. Cl. CPC H10K 59/131; H10K 59/1201; H10K 59/1213

(57) ABSTRACT

Disclosed are a display substrate and a preparation method therefor, and a display apparatus. The display substrate includes a plurality of repetition units (100), at least one repetition unit (100) includes a plurality of sub-pixels, and a sub-pixel includes a pixel drive circuit respectively connected with a scan signal line (30), a first power supply line (51), a data signal line (52), and a compensation signal line (53). In a direction perpendicular to the display substrate, the display substrate includes at least a semiconductor layer and a plurality of conductive layers disposed on a base substrate. The first power supply line (51), the data signal line (52), and the compensation signal line (53) are disposed on a side of the semiconductor layer close to the base substrate, and the scan signal line (30) is disposed on a side of the semiconductor layer away from the base substrate.

### CROSS-REFERENCE TO RELATED APPLICATION

The present application is a U.S. National Phase Entry of International Application No. PCT/CN 2023/091560 having an international filing date of Apr. 28, 2023, contents of which should be regarded as being incorporated herein by reference.

### TECHNICAL FIELD

The present disclosure relates to, but is not limited to, the field of display technologies, and in particular to a display substrate, a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matters described herein in detail. The summary is not intended to limit the protection scope of claims.

In one aspect, the present disclosure provides a display substrate including a plurality of repetition units, wherein at least one repetition unit includes a plurality of sub-pixels forming at least two pixel rows and two pixel columns, at least one sub-pixel includes a pixel drive circuit connected with a scan signal line, a first power supply line, a data signal line, and a compensation signal line, respectively, the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; in a direction perpendicular to the display substrate, the display substrate includes at least a semiconductor layer and a plurality of conductive layers disposed on a base substrate, wherein the first power supply line, the data signal line, and the compensation signal line are disposed on a side of the semiconductor layer close to the base substrate, and the scan signal line is disposed on a side of the semiconductor layer away from the base substrate.

In an exemplary implementation mode, in the direction perpendicular to the display substrate, the display substrate includes at least a first conductive layer, a second conductive layer, a first insulation layer, a semiconductor layer, a second insulation layer, and a third conductive layer disposed on the base substrate and sequentially disposed along a direction away from the base substrate, wherein the first power supply line, the data signal line, and the compensation signal line are disposed in the second conductive layer, and the scan signal line is disposed in the third conductive layer.

In an exemplary implementation mode, the third conductive layer further includes a plurality of connection electrodes, at least one connection electrode is simultaneously connected with the second conductive layer and the semiconductor layer through a via of an adapter structure, the via of the adapter structure includes at least two half holes, the first insulation layer and the second insulation layer in one half hole are removed to expose a surface of the second conductive layer, and the second insulation layer in the other half hole is removed to expose a surface of the semiconductor layer.

In an exemplary implementation mode, the at least one repetition unit further includes a power supply connection line, the power supply connection line is in a shape of a line extending along a pixel row direction, the first power supply line is in a shape of a line extending along a pixel column direction, and the power supply connection line is connected with the first power supply line to form a mesh structure for transmitting a first power supply signal in a mesh shape.

In an exemplary implementation mode, the power supply connection line and the first power supply line are disposed in different conductive layers, and the power supply connection line is connected with the first power supply line through a via.

In an exemplary implementation mode, the pixel drive circuit includes at least a first transistor, a second transistor, a third transistor, and a storage capacitor, wherein a first electrode of the first transistor is connected with the data signal line, a second electrode of the first transistor is connected with a gate electrode of the second transistor and a first end of the storage capacitor respectively, a first electrode of the second transistor is connected with the first power supply line, a second electrode of the second transistor is connected with a second electrode of the third transistor and a second end of the storage capacitor respectively, and a first electrode of the third transistor is connected with the compensation signal line; in a pixel drive circuit of at least one sub-pixel, a gate electrode of the first transistor and a gate electrode of the third transistor are connected with a same scan signal line.

In an exemplary implementation mode, in a plurality of pixel drive circuits of at least one pixel row, gate electrodes of a plurality of first transistors and gate electrodes of a plurality of third transistors are connected with a same scan signal line.

In an exemplary implementation mode, in a plurality of pixel drive circuits of at least one repetition unit, gate electrodes of a plurality of first transistors and gate electrodes of a plurality of third transistors are connected with a same scan signal line.

In an exemplary implementation mode, the scan signal line, the gate electrode of the first transistor, the gate electrode of the second transistor, and the gate electrode of the third transistor are disposed in a same layer.

In an exemplary implementation mode, in at least one repetition unit, gate electrodes of a plurality of first transistors and gate electrodes of a plurality of third transistors of adjacent pixel rows are connected with a same scan signal line.

In an exemplary implementation mode, the plurality of repetition units includes an (n−1)-th repetition unit row, an n-th repetition unit row, and an (n+1)-th repetition unit row, wherein n is a positive integer greater than 1, the n-th repetition unit row includes a first pixel row and a second pixel row, the first pixel row is located on a side of the second pixel row close to the (n'1)-th repetition unit row, the second pixel row is located on a side of the first pixel row close to the (n+1)-th repetition unit row; a first gate electrode and a third gate electrode included in the first pixel row in the n-th repetition unit row are all located on a side of the scan signal line close to the (n−1)-th repetition unit row, and a first gate electrode and a third gate electrode included in the second pixel row in the n-th repetition unit row are all located on a side of the scan signal line close to the (n+1)-th repetition unit row.

In an exemplary implementation mode, the first end of the storage capacitor includes a first electrode plate and a third electrode plate, and the second end of the storage capacitor includes a second electrode plate, an orthographic projection of the second electrode plate on the base substrate is at least partially overlapped with an orthographic projection of the first electrode plate on a plane of the display substrate, the first electrode plate and the second electrode plate form a first capacitor, an orthographic projection of the second electrode plate on the plane of the display substrate is at least partially overlapped with an orthographic projection of the third electrode plate on the plane of the display substrate, the third electrode plate and the second electrode plate form a second capacitor, the first electrode plate is respectively connected with the third electrode plate, the second electrode of the first transistor, and the gate electrode of the second transistor, the second electrode plate is respectively connected with the second electrode of the second transistor and the second electrode of the third transistor, and the first capacitor and the second capacitor construct a storage capacitor with a parallel structure.

In an exemplary implementation mode, in the direction perpendicular to the display substrate, the display substrate includes a drive circuit layer disposed on the base substrate, a color film structure layer disposed on a side of the drive circuit layer away from the base substrate, and a light emitting structure layer disposed on a side of the color film structure layer away from the base substrate, the drive circuit layer includes at least a first conductive layer, a second conductive layer, a semiconductor layer, and a third conductive layer sequentially disposed along a direction away from the base substrate, the light emitting structure layer includes at least a fourth conductive layer and a pixel definition layer sequentially disposed along the direction away from the base substrate; in at least one sub-pixel, the first electrode plate is disposed in the first conductive layer, the second electrode plate is disposed in the semiconductor layer, the third electrode plate is disposed in the fourth conductive layer, and the third electrode plate is connected with the first electrode plate through a via.

In an exemplary implementation mode, a plurality of sub-pixels in at least one repetition unit include a first sub-pixel, a second sub-pixel, a third sub-pixel, and a fourth sub-pixel, the first sub-pixel and the second sub-pixel form a first pixel row, the third sub-pixel and the fourth sub-pixel form a second pixel row, the first sub-pixel and the third sub-pixel form a first pixel column, and the second sub-pixel and the fourth sub-pixel form a second pixel column; the color film structure layer includes at least a red color film layer, a blue color film layer, and a green color film layer, wherein the red color film layer includes at least a red filter disposed in the first sub-pixel, the blue color film layer includes at least a blue filter disposed in the second sub-pixel, and the green color film layer includes at least a green filter disposed in the fourth sub-pixel.

In an exemplary implementation mode, the red color film layer further includes a shielding strip, a first shielding block, a second shielding block, a third shielding block, and a fourth shielding block; an orthographic projection of the shielding strip on the base substrate is at least partially overlapped with an orthographic projection of the scan signal line on the base substrate, an orthographic projection of the first shielding block on the base substrate is at least partially overlapped with an orthographic projection of a second transistor in the first sub-pixel on the base substrate, an orthographic projection of the second shielding block on the base substrate is at least partially overlapped with an orthographic projection of a second transistor in the second sub-pixel on the base substrate, an orthographic projection of the third shielding block on the base substrate is at least partially overlapped with an orthographic projection of a second transistor in the third sub-pixel on the base substrate, and an orthographic projection of the fourth shielding block on the base substrate is at least partially overlapped with an orthographic projection of a second transistor in the fourth sub-pixel on the base substrate.

In an exemplary implementation mode, the red color film layer further includes a shielding strip, a first shielding block, and a third shielding block, and the blue color film layer further includes a second shielding block and a fourth shielding block; an orthographic projection of the shielding strip on the base substrate is at least partially overlapped with an orthographic projection of the scan signal line on the base substrate, an orthographic projection of the first shielding block on the base substrate is at least partially overlapped with an orthographic projection of a second transistor in the first sub-pixel on the base substrate, an orthographic projection of the second shielding block on the base substrate is at least partially overlapped with an orthographic projection of a second transistor in the second sub-pixel on the base substrate, an orthographic projection of the third shielding block on the base substrate is at least partially overlapped with an orthographic projection of a second transistor in the third sub-pixel on the base substrate, and an orthographic projection of the fourth shielding block on the base substrate is at least partially overlapped with an orthographic projection of a second transistor in the fourth sub-pixel on the base substrate.

In an exemplary implementation mode, in at least one sub-pixel, the fourth conductive layer includes at least the third electrode plate, and a pixel opening exposing the third electrode plate is disposed on the pixel definition layer; in at least one repetition unit, at least one pixel slot is disposed on the pixel definition layer, the pixel slot includes any one or more of: a first pixel slot extending along a pixel row direction, and a second pixel slot extending along a pixel column direction.

In another aspect, the present disclosure also provides a display apparatus, including the display substrate described above.

In yet another aspect, the present disclosure also provides a preparation method of a display substrate, the display substrate includes a plurality of repetition units, at least one repetition unit includes a plurality of sub-pixels forming at least two pixel rows and two pixel columns, at least one sub-pixel includes a pixel drive circuit connected with a scan signal line, a first power supply line, a data signal line, and a compensation signal line, respectively, wherein the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; the preparation method includes: forming a semiconductor layer and a plurality of conductive layers on a base substrate, wherein the first power supply line, the data signal line, and the compensation signal line are disposed on a side of the semiconductor layer close to the base substrate, and the scan signal line is disposed on a side of the semiconductor layer away from the base substrate.

Other aspects may be comprehended upon reading and understanding drawings and detailed description.

### BRIEF DESCRIPTION OF DRAWINGS

Accompanying drawings are intended to provide further understanding of technical solutions of the present disclosure and constitute a part of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display apparatus.

FIG. 2 is a schematic diagram of a planar structure of a display substrate according to an exemplary embodiment of the present disclosure.

FIG. 3 is an equivalent circuit diagram of a pixel drive circuit in a repetition unit according to an exemplary embodiment of the present disclosure.

FIG. 4 is a schematic diagram of a structure of a drive circuit layer in a display substrate according to an embodiment of the present disclosure.

FIG. 5 is a schematic diagram of a structure of a color film structure layer in a display substrate according to an embodiment of the present disclosure.

FIG. 6 is a schematic diagram after a pattern of a first conductive layer is formed according to the present disclosure.

FIGS. 7A, 7B, and 7C are schematic diagrams after a pattern of a second conductive layer is formed according to the present disclosure.

FIGS. 8A, 8B, and 8C are schematic diagrams after a pattern of a semiconductor layer is formed according to the present disclosure.

FIGS. 9A and 9B are schematic diagrams after a pattern of a second insulation layer is formed according to the present disclosure.

FIGS. 10A to 10D are schematic diagrams after a pattern of a third conductive layer is formed according to the present disclosure.

FIGS. 11A and 11B are schematic diagrams after a pattern of a red color film layer is formed according to the present disclosure.

FIGS. 12A and 12B are schematic diagrams after a pattern of a green color film layer is formed according to the present disclosure.

FIGS. 13A and 13B are schematic diagrams after a pattern of a blue color film layer is formed according to the present disclosure.

FIG. 14 is a schematic diagram after a pattern of a planarization layer is formed according to the present disclosure.

FIGS. 15A and 15B are schematic diagrams after a pattern of a fourth conductive layer is formed according to the present disclosure.

FIG. 16 is a schematic diagram after a pattern of a pixel definition layer is formed according to the present disclosure.

FIG. 17 is a schematic diagram of a structure of a drive circuit layer in another display substrate according to an embodiment of the present disclosure.

FIG. 18 is a schematic diagram of a structure of a color film structure layer in another display substrate according to an embodiment of the present disclosure.

FIG. 19 is another schematic diagram after a pattern of a first semiconductor layer is formed according to the present disclosure.

FIGS. 20A and 20B are another schematic diagrams after a pattern of a second conductive layer is formed according to the present disclosure.

FIGS. 21A and 21B are another schematic diagrams after a pattern of a semiconductor layer is formed according to the present disclosure.

FIG. 22 is another schematic diagram after a pattern of a second insulation layer is formed according to the present disclosure.

FIGS. 23A and 23B are another schematic diagrams after a pattern of a third conductive layer is formed according to the present disclosure.

FIGS. 24A and 24B are another schematic diagrams after a pattern of a red color film layer is formed according to the present disclosure.

FIGS. 25A and 25B are another schematic diagrams after a pattern of a green color film layer is formed according to the present disclosure.

FIGS. 26A and 26B are another schematic diagrams after a pattern of a blue color film layer is formed according to the present disclosure.

FIG. 27 is another schematic diagram after a pattern of a planarization layer is formed according to the present disclosure.

FIGS. 28A and 28B are another schematic diagrams after a pattern of a fourth conductive layer is formed according to the present disclosure.

FIG. 29 is another schematic diagram after a pattern of a pixel definition layer is formed according to the present disclosure.

Reference signs are described as follows.

| | | |
|---|---|---|
| 10-base substrate; | 10A-first insulation layer; | 10B-second insulation layer; |
| 11-first connection electrode; | 12-second connection electrode; | 13-third connection electrode; |
| 14-fourth connection electrode; | 15-fifth connection electrode; | 16-sixth connection electrode; |
| 17-seventh connection electrode; | 18-eighth connection electrode; | 19-ninth connection electrode; |
| 20-tenth connection electrode; | 21-first active layer; | 22-second active layer; |
| 23-third active layer; | 30-scan signal line; | 31-first gate electrode; |
| 32-second gate electrode; | 33-third gate electrode; | 41-red filter; |
| 42-blue filter; | 43-green filter; | 51-first power supply line; |
| 52-data signal line; | 53-compensation signal line; | 54-power supply connection line; |
| 61-first electrode plate; | 62-second electrode plate; | 63-third electrode plate; |
| 70-shielding strip; | 71-first shielding block; | 72-second shielding block; |
| 73-third shielding block; | 74-fourth shielding block; | 100-repetition unit. |

### DETAILED DESCRIPTION

To make objectives, the technical solutions, and advantages of the present disclosure clearer, the embodiments of the present disclosure will be described in detail below in combination with the accompany drawings. Implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that a referred apparatus or element must have a specific orientation and be structured and operated with the specific orientation but only to easily and simply describe the specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is- 5°or more and 5°or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within a range of process and measurement errors are allowed.

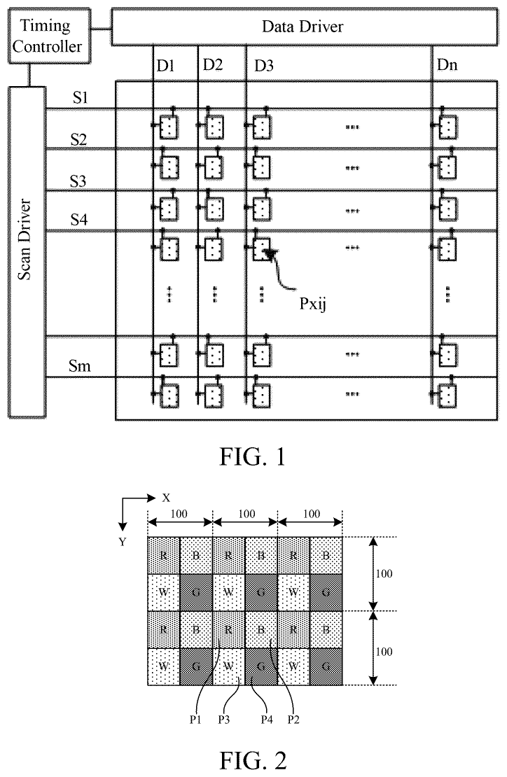

FIG. 1 is a schematic diagram of a structure of a display apparatus. As shown in FIG. 1, an OLED display apparatus may include a timing controller, a data driver, a scan driver, and a pixel array. The timing controller is connected with the data driver and the scan driver respectively, the data driver is connected with multiple data signal lines (D1 to Dn) respectively, and the scan driver is connected with multiple scan signal lines (S1 to Sm) respectively. The sub-pixel array may include multiple sub-pixels Pxij. Each sub-pixel Pxij may be connected with a corresponding data signal line and a corresponding scan signal line, wherein i and j may be natural numbers. At least one sub-pixel Pxij may include at least a circuit unit and a display unit. The circuit unit may include at least a pixel drive circuit connected with a scan signal line and a data signal line, respectively. The display unit may include at least a light emitting device connected with the pixel drive circuit of the circuit unit, and the sub-pixel PXij may refer to a sub-pixel in which a pixel drive circuit is connected with an i-th scan signal line and a j-th data signal line. In an exemplary implementation mode, the timing controller may provide a control signal and a grayscale value suitable for a specification of the data driver to the data driver, and may provide a scan start signal, a clock signal, etc. suitable for a specification of the scan driver and the like to the scan driver. The data driver may generate a data voltage to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal, etc. from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on level pulse to a next-stage circuit under control of the clock signal, wherein m may be a natural number. In an exemplary implementation mode, the pixel array may be disposed on the display substrate.

An exemplary embodiment of the present disclosure provides a display substrate including a plurality of repetition units, at least one repetition unit includes a plurality of sub-pixels forming at least two pixel rows and two pixel columns, at least one sub-pixel includes a pixel drive circuit connected with a scan signal line, a first power supply line, a data signal line, and a compensation signal line, respectively, wherein the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; in a direction perpendicular to the display substrate, the display substrate includes at least a semiconductor layer and a plurality of conductive layers disposed on a base substrate, wherein the first power supply line, the data signal line, and the compensation signal line are disposed on a side of the semiconductor layer close to the base substrate, and the scan signal line is disposed on a side of the semiconductor layer away from the base substrate.

In an exemplary implementation mode, in the direction perpendicular to the display substrate, the display substrate includes at least a first conductive layer, a second conductive layer, a first insulation layer, a semiconductor layer, a second insulation layer, and a third conductive layer disposed on the base substrate and sequentially disposed along a direction away from the base substrate, wherein the first power supply line, the data signal line, and the compensation signal line are disposed in the second conductive layer, and the scan signal line is disposed in the third conductive layer.

In an exemplary implementation mode, the third conductive layer further includes a plurality of connection electrodes, at least one connection electrode is simultaneously connected with the second conductive layer and the semiconductor layer through a via of an adapter structure, the via of the adapter structure includes at least two half holes, the first insulation layer and the second insulation layer in one half hole are removed to expose a surface of the second conductive layer, and the second insulation layer in the other half hole is removed to expose a surface of the semiconductor layer.

In an exemplary implementation mode, the pixel drive circuit includes at least a first transistor, a second transistor, a third transistor, and a storage capacitor, wherein a first electrode of the first transistor is connected with the data signal line, a second electrode of the first transistor is connected with a gate electrode of the second transistor and a first end of the storage capacitor respectively, a first electrode of the second transistor is connected with the first power supply line, a second electrode of the second transistor is connected with a second electrode of the third transistor and a second end of the storage capacitor respectively, and a first electrode of the third transistor is connected with the compensation signal line; in a pixel drive circuit of at least one sub-pixel, a gate electrode of the first transistor and a gate electrode of the third transistor are connected with a same scan signal line.

In an exemplary implementation mode, a first end of the storage capacitor includes a first electrode plate and a third electrode plate, and a second end of the storage capacitor includes a second electrode plate, an orthographic projection of the second electrode plate on the base substrate is at least partially overlapped with an orthographic projection of the first electrode plate on a plane of the display substrate, the first electrode plate and the second electrode plate form a first capacitor, an orthographic projection of the second electrode plate on the plane of the display substrate is at least partially overlapped with an orthographic projection of the third electrode plate on the plane of the display substrate, the third electrode plate and the second electrode plate form a second capacitor, the first electrode plate is respectively connected with the third electrode plate, the second electrode of the first transistor, and the gate electrode of the second transistor, the second electrode plate is respectively connected with the second electrode of the second transistor and the second electrode of the third transistor, and the first capacitor and the second capacitor construct a storage capacitor with a parallel structure.

The display substrate of the present disclosure is illustrated with examples below through some exemplary embodiments.

FIG. 2 is a schematic diagram of a planar structure of a display substrate according to an exemplary embodiment of the present disclosure. As shown in FIG. 2, in an exemplary implementation mode, in a direction parallel to the display substrate, the display substrate may include a plurality of repetition units 100, and at least one repetition unit 100 may include a plurality of sub-pixels, and the plurality of sub-pixels may include a first sub-pixel P1 emitting light of a first color, a second sub-pixel P2 emitting light of a second color, a third sub-pixel P3 emitting light of a third color, and a fourth sub-pixel P4 emitting light of a fourth color. In an exemplary implementation mode, the repetition units are basic units constituting the display substrate, and the display substrate is constructed by repeating and continuously disposing the repetition units along at least one direction, i.e., the display substrate is formed by splicing a plurality of repetition units.

In an exemplary implementation mode, the four sub-pixels may be arranged in a square manner, which may effectively increase an aperture ratio and a light transmission region area.

In an exemplary implementation mode, in at least one repetition unit 100, a second sub-pixel P2 may be disposed on a side of a first sub-pixel P1 in a first direction X, a third sub-pixel P3 may be disposed on a side of the first sub-pixel P1 in a second direction Y, and a fourth sub-pixel P4 may be disposed on a side of the third sub-pixel P3 in the first direction X. A plurality of sub-pixels sequentially disposed along the first direction X may be referred to as a pixel row. A plurality of sub-pixels sequentially disposed along the second direction Y may be referred to as a pixel column. A plurality of pixel rows and a plurality of pixel columns construct a pixel array arranged in an array, the first direction X intersecting with the second direction Y.

In an exemplary implementation mode, the first sub-pixel P1 may be a red sub-pixel (R) emitting red light, the second sub-pixel P2 may be a blue sub-pixel (B) emitting blue light, the third sub-pixel P3 may be a white sub-pixel (W) emitting white light, and the fourth sub-pixel P4 may be a green sub-pixel (G) emitting green light. In some possible implementation modes, an arrangement mode of RBWG may be adjusted according to actual needs, and the present disclosure is not specifically limited thereto.

In an exemplary implementation mode, in a direction perpendicular to the display substrate, the display substrate may include at least a drive circuit layer disposed on the base substrate, a color film structure layer disposed on a side of the drive circuit layer away from the base substrate, and a light emitting structure layer disposed on a side of the color film structure layer away from the base substrate. In at least one repetition unit, the drive circuit layer may include a plurality of circuit units. A circuit unit may include at least a pixel drive circuit connected with a scan signal line and a data signal line, respectively. The pixel drive circuit is configured to receive a data voltage transmitted by the data signal line and output a corresponding current to a light emitting device under control of the scan signal line. The color film structure layer may include a plurality of color film units, and a color film unit may include at least a color filter layer configured to enable a corresponding sub-pixel to emit light of a desired color. The light emitting structure layer may include a plurality of light emitting units, and a light emitting unit may include at least a light emitting device. The light emitting device is connected with a pixel drive circuit of a circuit unit of a sub-pixel in which the light emitting device is located, and the light emitting device is configured to emit light with corresponding brightness in response to a current output by the pixel drive circuit of the sub-pixel in which the light emitting device is located.

In an exemplary implementation mode, the circuit unit mentioned in the present disclosure refers to a region divided by a pixel drive circuit. The color film unit mentioned in the present disclosure refers to a region divided by a color filter layer. The display unit mentioned in the present disclosure refers to a region divided by a light emitting device. Positions of an orthographic projection of a circuit unit on the base substrate, an orthographic projection of a color filter layer on the base substrate, and an orthographic projection of a light emitting unit on the base substrate may or may not correspond.

In an exemplary embodiment of the present disclosure, the positions of an orthographic projection of a circuit unit on the base substrate, an orthographic projection of a color filter layer on the base substrate, and an orthographic projection of a light emitting unit on the base substrate are in one-to-one correspondence. The circuit unit, the color film unit, and the light emitting unit constitute a sub-pixel, so a sub-pixel is uniformly used to refer to a circuit unit, a color film unit, and a light emitting unit in the following.

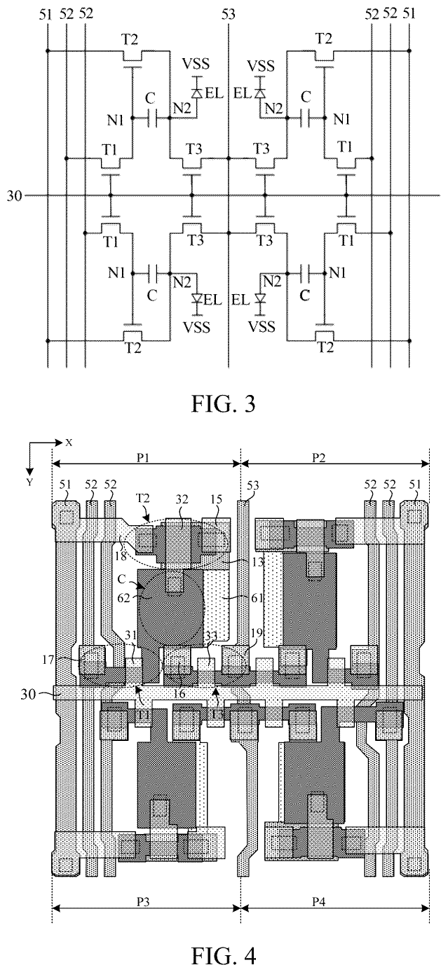

FIG. 3 is an equivalent circuit diagram of a pixel drive circuit in a repetition unit according to an exemplary embodiment of the present disclosure. As shown in FIG. 4, at least one repetition unit may include four pixel drive circuits, the four pixel drive circuits may be arranged in a square manner, and the pixel drive circuits may be of a 3T1C structure.

In an exemplary implementation mode, at least one pixel drive circuit may include three transistors (a first transistor T1, a second transistor T2, and a third transistor T3) and one storage capacitor C. The pixel drive circuit is connected with a scan signal line 30, a first power supply line 51, a data signal line 52, and a compensation signal line 53, respectively.

In an exemplary implementation mode, the pixel drive circuit may include a first node N1 and a second node N2. The first node N1 is connected with a second electrode of the first transistor T1, a gate electrode of the second transistor T2 and a first end of the storage capacitor C, respectively, and the second node N2 is connected with a second electrode of the second transistor T2, a second electrode of the third transistor T3 and a second end of the storage capacitor C, respectively.

In an exemplary implementation mode, the first end of the storage capacitor C is connected with the first node N1, the second end of the storage capacitor C is connected with the second node N2, and the storage capacitor C is configured to store a potential of the gate electrode of the second transistor T2.

In an exemplary implementation mode, the first transistor T1 is a switching transistor, the second transistor T2 is a drive transistor, and the third transistor T3 is a compensation transistor.

In an exemplary implementation mode, a gate electrode of the first transistor T1 is connected with the scan signal line 30, a first electrode of the first transistor T1 is connected with the data signal line 52, and a second electrode of the first transistor T1 is connected with the first node N1. When a turned-on signal is applied to the scan signal line 30, the first transistor T1 inputs a data signal of the data signal line 52 to the gate electrode of the second transistor T2.

In an exemplary implementation mode, the gate electrode of the second transistor T2 is connected with the first node N1, a first electrode of the second transistor T2 is connected with the first power supply line 51, and the second electrode of the second transistor T2 is connected with the second node N2. The second transistor T2 generates a corresponding current at the second electrode of the second transistor T2 under control of a data signal received by the gate electrode of the second transistor T2.

In an exemplary implementation mode, a gate electrode of the third transistor T3 is connected with the scan signal line 30, a first electrode of the third transistor T3 is connected with the compensation signal line 53, and a second electrode of the third transistor T3 is connected with the second node N2. When a turned-on signal is applied to the scan signal line 30, the third transistor T3 extracts a threshold voltage Vth and a migration rate of the second transistor T2 in response to a compensation timing, to compensate the threshold voltage Vth.

In an exemplary implementation mode, in a pixel drive circuit of at least one sub-pixel, a gate electrode of a first transistor T1 and a gate electrode of a third transistor T3 are connected with a same scan signal line 30.

In an exemplary implementation mode, in a plurality of pixel drive circuits of at least one pixel row, gate electrodes of a plurality of first transistors T1 and gate electrodes of a plurality of third transistors T3 are connected with a same scan signal line 30.

In an exemplary implementation mode, in a plurality of pixel drive circuits of at least one repetition unit, gate electrodes of a plurality of first transistors T1 and gate electrodes of a plurality of third transistors T3 are connected with a same scan signal line 30.

In an exemplary implementation mode, a light emitting device EL may be an OLED including a first electrode (anode), an organic emitting layer, and a second electrode (cathode), which are stacked, or may be a QLED including a first electrode (anode), a quantum dot emitting layer, and a second electrode (cathode), which are stacked. The first electrode of the light emitting device EL is connected with the second node N2, the second electrode of the light emitting device EL is connected with the second power supply line 52, and the light emitting device EL emits light with corresponding brightness in response to a current of the second electrode of the second transistor T2.

In an exemplary implementation mode, a signal of the first power supply line 51 is a continuously supplied high-level signal, and a signal of the second power supply line 52 is a continuously supplied low-level signal.

In an exemplary implementation mode, the first transistor T1 to the third transistor T3 may be P-type transistors, or may be N-type transistors. Use of a same type of transistors in a pixel drive circuit may simplify a process flow, reduce a process difficulty of a display panel, and improve a product yield. In some possible implementation modes, the first transistor T1 to the third transistor T3 may include a P-type transistor and an N-type transistor.

In an exemplary implementation mode, for the first transistor T1 to the third transistors T3, low temperature poly silicon thin film transistors may be used, oxide thin film transistors may be used, or a low temperature poly silicon thin film transistor and an oxide thin film transistor may be used. An active layer of a low temperature poly silicon thin film transistor may be made of Low Temperature Poly Silicon (LTPS for short), and an active layer of an oxide thin film transistor may be made of an oxide semiconductor (Oxide). The low temperature poly silicon thin film transistor has advantages, such as a high migration rate and fast charging, and the oxide thin film transistor has advantages, such a low leakage current. The low temperature poly silicon thin film transistor and the oxide thin film transistor are integrated on one display substrate, that is a LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

FIG. 4 is a schematic diagram of a structure of a drive circuit layer in a display substrate according to an exemplary embodiment of the present disclosure, illustrating a structure of a pixel drive circuit in a repetition unit (four sub-pixels) in a bottom emission display substrate. In an exemplary implementation mode, at least one repetition unit may include a first sub-pixel P1, a second sub-pixel P2, a third sub-pixel P3, and a fourth sub-pixel P4 arranged in a square manner, each sub-pixel includes a pixel drive circuit.

In an exemplary implementation mode, at least one repetition unit may include one scan signal line 30, two first power supply lines 51, four data signal lines 52, and one compensation signal line 53, and the aforementioned signal lines are each connected with pixel drive circuits in the four sub-pixels. The scan signal line 30 is configured to provide a scan signal to a pixel drive circuit. A first power supply line 51 is configured to provide a power supply signal to the pixel drive circuit. A data signal line 52 is configured to provide a data signal to the pixel drive circuit. The compensation signal line 53 is configured to provide a compensation signal to the pixel drive circuit.

In an exemplary implementation mode, a main body portion of the scan signal line 30 extends along the first direction X and may be disposed in a middle of the repetition unit in the second direction Y. Main body portions of the first power supply lines 51, the data signal lines 52, and the compensation signal line 53 extend along the second direction Y. The two first power supply lines 51 may be located on two sides of the repetition unit in the first direction X. The four data signal lines 52 and the compensation signal line 53 may be located between the two first power supply lines 51. Two data signal lines 52 of the four data signal lines 52 may be located between one first power supply line 51 and the compensation signal line 53, and the other two data signal lines 52 of the four data signal lines 52 may be located between another first power supply line 51 and the compensation signal line 53. Thus, one scan signal line 30 extending along the first direction X, two first power supply lines 51 extending along the second direction Y, and one compensation signal line 53 extending along the second direction Y define a first sub-pixel P1, a second sub-pixel P2, a third sub-pixel P3, and a fourth sub-pixel P4 of one repetition unit.

In an exemplary implementation mode, in at least one repetition unit, four sub-pixels may be mirror-symmetrical with respect to the scan signal line 30, and four sub-pixels may be mirror-symmetrical with respect to the compensation signal line 53.

In an exemplary implementation mode, a pixel drive circuit of at least one sub-pixel may include a first transistor T1, a second transistor T2, a third transistor T3, and a storage capacitor C. The first transistor T1, the second transistor T2, and the third transistor T3 may each include an active layer, a gate electrode, a first electrode, and a second electrode. The storage capacitor C may include a first end and a second end. In an exemplary implementation mode, a first electrode of the first transistor T1 is connected with a data signal line 52. A second electrode of the first transistor T1 is connected with a gate electrode of the second transistor T2 and the first end of the storage capacitor C, respectively. A first electrode of the second transistor T2 is connected with a first power supply line 51. A second electrode of the second transistor T2 is connected with a second electrode of the third transistor T3 and the second end of the storage capacitor C, respectively. A first electrode of the third transistor T3 is connected with the compensation signal line 53.

In an exemplary implementation mode, in a pixel drive circuit of at least one sub-pixel, a gate electrode of the first transistor T1 and a gate electrode of the third transistor T3 are connected with a same scan signal line 30.

In an exemplary implementation mode, in a plurality of pixel drive circuits of at least one pixel row, gate electrodes of a plurality of first transistors T1 and gate electrodes of a plurality of third transistors T3 are connected with a same scan signal line 30.

In an exemplary implementation mode, in a plurality of pixel drive circuits of at least one repetition unit, gate electrodes of a plurality of first transistors T1 and gate electrodes of a plurality of third transistors T3 are connected with a same scan signal line 30.

In an exemplary implementation mode, in a direction perpendicular to the display substrate, the display substrate may include a base substrate, and a semiconductor layer and a plurality of conductive layers disposed on the base substrate. A first power supply line 51, a data signal line 52, and a compensation signal line 53 may be disposed on a side of the semiconductor layer close to the base substrate, and a scan signal line 30 may be disposed on a side of the semiconductor layer away from the base substrate.

In an exemplary implementation mode, in a direction perpendicular to the display substrate, the display substrate may include a base substrate, a first conductive layer disposed on the base substrate, a second conductive layer disposed on a side of the first conductive layer away from the base substrate, a first insulation layer disposed on a side of the second conductive layer away from the base substrate, a semiconductor layer disposed on a side of the first insulation layer away from the base substrate, a second insulation layer disposed on a side of the semiconductor layer away from the base substrate, and a third conductive layer disposed on a side of the second insulation layer away from the base substrate.

In an exemplary implementation mode, the first conductive layer may include at least a first electrode plate 61 of a storage capacitor. The second conductive layer may include at least a third connection electrode 13 as a shielding layer, a first power supply line 51, a data signal line 52, and a compensation signal line 53. The semiconductor layer may include at least active layers of three transistors and a second electrode plate 62 of the storage capacitor. The third conductive layer may include at least a scan signal line 30.

In an exemplary implementation mode, the third conductive layer may further include a first gate electrode 31, a second gate electrode 32, and a third gate electrode 33, i.e., the scan signal line 30, the first gate electrode 31, the second gate electrode 32, and the third gate electrode 33 are disposed in a same layer and are formed synchronously through a same patterning process.

In an exemplary implementation mode, the first gate electrode 31 and the third gate electrode 33 are connected with the scan signal line 30, and the second gate electrode 32 is connected with the second electrode plate 62.

In the exemplary implementation mode, the scan signal line 30, the first gate electrode 31, and the third gate electrode 33 are of an interconnected integral structure.

In an exemplary implementation mode, in a plurality of pixel drive circuits of adjacent pixel rows, gate electrodes of a plurality of first transistors T1 and gate electrodes of a plurality of third transistors T3 are connected with a same scan signal line 30.

In an exemplary implementation mode, a plurality of repetition units of the display substrate may include an (n−1)-th repetition unit row, an n-th repetition unit row, and an (n+1)-th repetition unit row sequentially disposed along the second direction Y, wherein n is a positive integer greater than 1, and each repetition unit row may include a first pixel row and a second pixel row. The first pixel row may include a plurality of first sub-pixels and a plurality of second sub-pixels, and the second pixel row may include a plurality of third sub-pixels and a plurality of fourth sub-pixels. For example, in the n-th repetition unit row, the first pixel row is located on a side of the second pixel row close to the (n−1)-th repetition unit row, and the second pixel row is located on a side of the first pixel row close to the (n+1)-th repetition unit row.

In an exemplary implementation mode, first gate electrodes and third gate electrodes included in the first pixel row in the n-th repetition unit row are all located on a side of the scan signal line 30 close to the (n−1)-th repetition unit row, and first gate electrodes and third gate electrodes included in the second pixel row in the n-th repetition unit row are all located on a side of the scan signal line 30 close to the (n+1)-th repetition unit row.

In an exemplary implementation mode, in at least one repetition unit row, first gate electrodes and third gate electrodes included in the first pixel row have a first distance from the scan signal line 30, first gate electrodes and third gate electrodes included in the second pixel row have a second distance from the scan signal line 30, and a ratio of the first distance to the second distance may be about 0.95 to 1.05.

In an exemplary implementation mode, the first distance and the second distance may be substantially equal.

In an exemplary implementation mode, the third conductive layer may further include a fifth connection electrode 15, a sixth connection electrode 16, a seventh connection electrode 17, an eighth connection electrode 18, and a ninth connection electrode 19, at least one of the above connection electrodes is simultaneously connected with the second conductive layer and the semiconductor layer through a via of an adapter structure. The via of the adapter structure includes at least two half holes, the first insulation layer and the second insulation layer in one half hole are removed to expose a surface of the second conductive layer, and the second insulation layer in the other half hole is removed to expose a surface of the semiconductor layer.

In an exemplary implementation mode, the fifth connection electrode 15 may achieve a connection of a second electrode of a second transistor T2 with a first electrode plate 61 through the via of the adapter structure.

In an exemplary implementation mode, the sixth connection electrode 16 may achieve a connection of a second electrode of a third transistor T3 with a first electrode plate 61 through the via of the adapter structure.

In an exemplary implementation mode, the seventh connection electrode 17 may achieve a connection of a data signal line 52 with a first electrode of a first transistor T1 through the via of the adapter structure.

In an exemplary implementation mode, the eighth connection electrode 18 may achieve a connection of a first power supply line 51 with a first electrode of a second transistor T2 through the via, and a second electrode of the second transistor T2 is connected with a second electrode plate 62.

In an exemplary implementation mode, the ninth connection electrode 19 may achieve a connection of a compensation signal line 53 with a first electrode of a third transistor T3 through the via of the adapter structure.

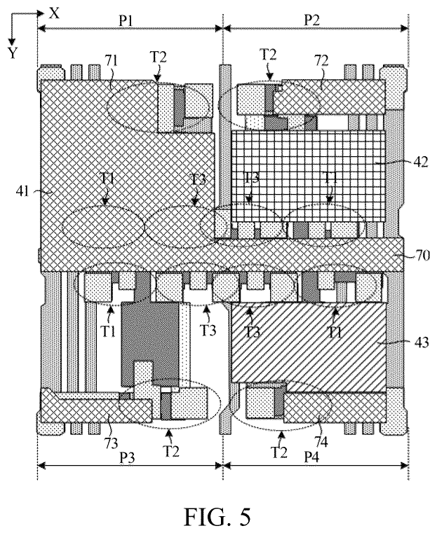

FIG. 5 is a schematic diagram of a structure of a color film structure layer in a display substrate according to an exemplary embodiment of the present disclosure, illustrating a structure of a color filter layer in a repetition unit (four sub-pixels) in a bottom emission display substrate. As shown in FIG. 5, in an exemplary implementation mode, at least one repetition unit may include a first sub-pixel P1, a second sub-pixel P2, a third sub-pixel P3, and a fourth sub-pixel P4 arranged in a square manner, each sub-pixel includes a color filter layer.

In an exemplary implementation mode, the color film structure layer may include at least a red color film layer, a blue color film layer, and a green color film layer. The red color film layer may include at least a red filter 41 disposed in the first sub-pixel P1, the blue color film layer may include at least a blue filter 42 disposed in the second sub-pixel P2, and the green color film layer may include at least a green filter 43 disposed in the fourth sub-pixel P4.

In an exemplary implementation mode, the red color film layer may further include a shielding strip 70, a first shielding block 71, a second shielding block 72, a third shielding block 73, and a fourth shielding block 74.

In an exemplary implementation mode, the shielding strip 70 may have a shape of a strip extending along the first direction X and may be disposed in a middle of the repetition unit in the second direction Y, and an orthographic projection of the shielding strip 70 on the base substrate is at least partially overlapped with an orthographic projection of the scan signal line 30 on the base substrate.

In an exemplary implementation mode, the first shielding block 71 may be disposed in the first sub-pixel P1, and an orthographic projection of the first shielding block 71 on the base substrate is at least partially overlapped with an orthographic projection of a second transistor T2 in the first sub-pixel P1 on the base substrate.

In an exemplary implementation mode, the second shielding block 72 may be disposed in the second sub-pixel P2, and an orthographic projection of the second shielding block 72 on the base substrate is at least partially overlapped with an orthographic projection of a second transistor T2 in the second sub-pixel P2 on the base substrate.

In an exemplary implementation mode, the third shielding block 73 may be disposed in the third sub-pixel P3, and an orthographic projection of the third shielding block 73 on the base substrate is at least partially overlapped with an orthographic projection of a second transistor T2 in the third sub-pixel P3 on the base substrate.

In an exemplary implementation mode, the fourth shielding block 74 may be disposed in the fourth sub-pixel P4, and an orthographic projection of the fourth shielding block 74 on the base substrate is at least partially overlapped with an orthographic projection of a second transistor T2 in the fourth sub-pixel P4 on the base substrate.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation mode, taking four sub-pixels (a first sub-pixel P1, a second sub-pixel P2, a third sub-pixel P3, and a fourth sub-pixel P4) of a repetition unit as an example, a preparation process of a display substrate according to the embodiment may include following operations.

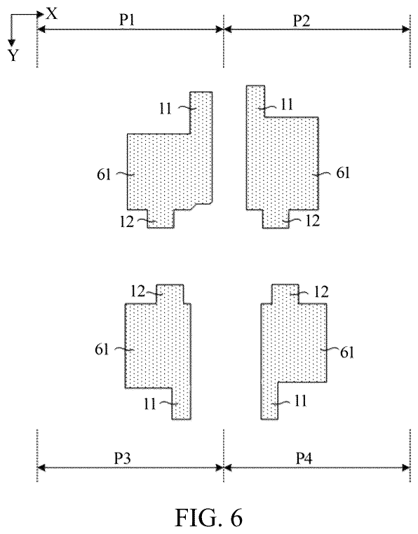

(101) A pattern of a first conductive layer is formed. In an exemplary implementation mode, forming the pattern of the first conductive layer includes depositing a first conductive thin film on a base substrate, patterning the first conductive thin film through a patterning process to forming the pattern of the first conductive layer on the base substrate, as shown in FIG. 6.

In an exemplary implementation mode, the first conductive layer of each sub-pixel in the display substrate may at least include a first connection electrode 11, a second connection electrode 12, and a first electrode plate 61.

In an exemplary implementation mode, the first electrode plate 61 may have a rectangular shape. Corners of the rectangular shape may be provided with chamfers. The first electrode plate 61 may serve as a transparent lower electrode plate of a transparent storage capacitor. The first electrode plate 61 is configured to form a transparent first capacitor with a second electrode plate to be formed subsequently.

In an exemplary implementation mode, the first connection electrode 11 may have a shape of a strip with a main body portion extending along the first direction X. A first end of the first connection electrode 11 is connected with a first electrode plate 61. A second end of the first connection electrode 11 extends toward a direction away from the first electrode plate 61. The first connection electrode 11 is configured to be connected with a third connection electrode to be formed subsequently.

In an exemplary implementation mode, the second connection electrode 12 may have a rectangular shape. A first end of the second connection electrode 12 is connected with the first electrode plate 61. A second end of the second connection electrode 12 extends toward a direction away from the first electrode plate 61. The second connection electrode 12 is configured to be connected with a fourth connection electrode to be formed subsequently.

In an exemplary implementation mode, in the first sub-pixel P1 and the second sub-pixel P2, the first connection electrode 11 may be disposed on a side of the first electrode plate 61 in an opposite direction of the second direction Y, and the second connection electrode 12 may be disposed on a side of the first electrode plate 61 in the second direction Y. In the third sub-pixel P3 and the fourth sub-pixel P4, the first connection electrode 11 may be disposed on a side of the first electrode plate 61 in the second direction Y, and the second connection electrode 12 may be disposed on a side of the first electrode plate 61 in an opposite direction of the second direction Y.

In an exemplary implementation mode, in a first pixel column, an edge of the first connection electrode 11 on a side close to a second pixel column and an edge of the first electrode plate 61 on a side close to the second pixel column may be substantially flush. In the second pixel column, an edge of the first connection electrode 11 on a side close to the first pixel column and an edge of the first electrode plate 61 on a side close to the first pixel column may be substantially flush.

In an exemplary implementation mode, the first connection electrode 11, the second connection electrode 12, and the first electrode plate 61 of each sub-pixel may be of an interconnected integral structure.

In an exemplary implementation mode, an area of the first electrode plate 61 in each sub-pixel may be substantially the same, so that a capacity of a storage capacitor in each sub-pixel is substantially the same.

In an exemplary implementation mode, positions of respective patterns in a first conductive layer in the first sub-pixel P1 and positions of respective patterns in a first conductive layer in the third sub-pixel P3 may be substantially mirror-symmetrical with respect to a horizontal reference line, positions of respective patterns in a first conductive layer in the second sub-pixel P2 and positions of respective patterns in a first conductive layer in the fourth sub-pixel P4 may be substantially mirror-symmetrical with respect to the horizontal reference line, the positions of the respective patterns in the first conductive layer in the first sub-pixel P1 and the positions of the respective patterns in the first conductive layer in the second sub-pixel P2 may be substantially mirror-symmetrical with respect to a vertical reference line, and the positions of the respective patterns in the first conductive layer in the third sub-pixel P3 and the positions of the respective patterns in the first conductive layer in the fourth sub-pixel P4 may be substantially mirror-symmetrical with respect to the vertical reference line. The horizontal reference line may be a straight line extending along the first direction X and bisecting a repetition unit in the second direction Y, and the vertical reference line may be a straight line extending along the second direction Y and bisecting a repetition unit in the first direction X

In an exemplary implementation mode, the first conductive layer may be made of a transparent conductive material, such as Indium Tin Oxide (ITO) or Indium Zinc Oxide (IZO).

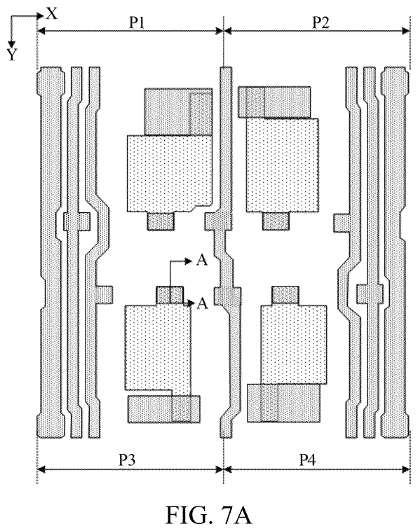

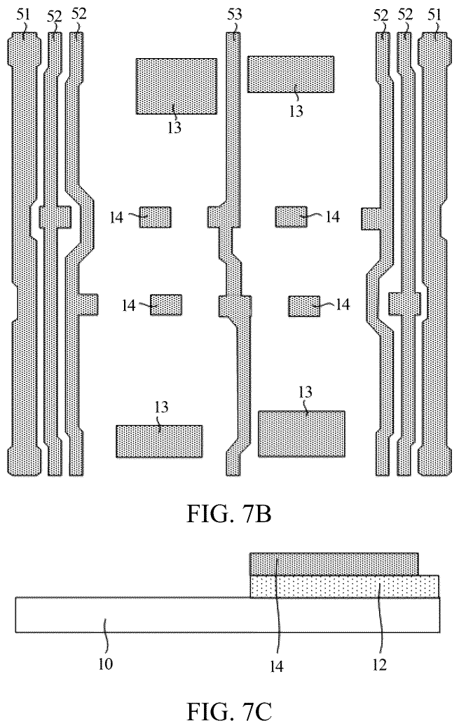

(102) A pattern of a second conductive layer is formed. In an exemplary implementation mode, forming the pattern of the second conductive layer may include depositing a second conductive thin film on the base substrate on which the aforementioned pattern is formed, and patterning the second conductive thin film through a patterning process to form the second conductive layer, as shown in FIGS. 7A, 7B, and 7C, wherein FIG. 7B is a schematic diagram of the second conductive layer in FIG. 7A and FIG. 7C is a cross-sectional view taken along an A-A direction in FIG. 7A.

In an exemplary implementation mode, a second conductive layer of each sub-pixel in the display substrate may include at least a third connection electrode 13 and a fourth connection electrode 14.

In an exemplary implementation mode, the third connection electrode 13 may have a rectangular shape, and may be located on a side of the first electrode plate 61 away from the second connection electrode 12. An orthographic projection of the third connection electrode 13 on the base substrate is at least partially overlapped with an orthographic projection of the first connection electrode 11 on the base substrate, and the third connection electrode 13 is directly lapped with the first connection electrode 11. In an exemplary implementation mode, on one hand, the third connection electrode 13 is configured to be connected with a fifth connection electrode to be formed subsequently, and, on the other hand, the third connection electrode 13 is configured to shade a second transistor, so as to reduce an intensity of light irradiated on the second transistor, reduce a leakage current of the second transistor, thereby reducing an influence of illumination on characteristics of the second transistor.

In an exemplary implementation mode, the fourth connection electrode 14 may have a rectangular shape and may be located on a side of the first electrode plate 61 away from the first connection electrode 11. An orthographic projection of the fourth connection electrode 14 on the base substrate is at least partially overlapped with an orthographic projection of the second connection electrode 12 on the base substrate, and the fourth connection electrode 14 is directly lapped with the second connection electrode 12. The fourth connection electrode 14 is configured to be connected with a sixth connection electrode to be formed subsequently.

In an exemplary implementation mode, a second conductive layer of each repetition unit in the display substrate may include at least two first power supply lines 51, four data signal lines 52, and one compensation signal line 53.

In an exemplary implementation mode, main body portions of the first power supply lines 51, the data signal lines 52, and the compensation signal line 53 extend along the second direction Y. A first first power supply line 51 may be located on a side of the repetition unit in an opposite direction of the first direction X. A second first power supply line 51 may be located on a side of the repetition unit in the first direction X. The compensation signal line 53 may be located between the two first power supply lines 51. Two of the four data signal lines 52 may be located between the first first power supply line 51 and the compensation signal line 53, and the other two of the four data signal lines 52 may be located between the second first power supply line 51 and the compensation signal line 53.

In an exemplary implementation mode, the first first power supply line 51 and the compensation signal line 53 may define a first pixel column, and two data signal lines 52 are disposed in the first pixel column. The second first power supply line 51 and the compensation signal line 53 may define a second pixel column, and two data signal lines 52 are disposed in the second pixel column.

In an exemplary implementation mode, positions of two first power supply lines 51 may be substantially mirror-symmetrical with respect to a vertical reference line. Positions of two data signal lines 52 located on a side of the compensation signal line 53 in an opposite direction of the first direction X and positions of two data signal lines 52 located on a side of the compensation signal line 53 in the first direction X may be substantially mirror-symmetrical with respect to the vertical reference line. Positions of a third connection electrode 13 and a fourth connection electrode 14 in the first sub-pixel P1 and positions of a third connection electrode 13 and a fourth connection electrode 14 in the third sub-pixel P3 may be substantially mirror-symmetrical with respect to a horizontal reference line. Positions of a third connection electrode 13 and a fourth connection electrode 14 in the second sub-pixel P2and positions of a third connection electrode 13 and a fourth connection electrode 14 in the fourth sub-pixel P4 may be substantially mirror-symmetrical with respect to the horizontal reference line.

In an exemplary implementation mode, the first power supply lines 51, the data signal lines 52, and the compensation signal line 53 may be straight lines or fold lines with an equal width, or straight lines or fold lines with unequal widths. Using straight lines or fold lines with variable widths may not only facilitate a layout of a pixel structure, but also reduce parasitic capacitance.

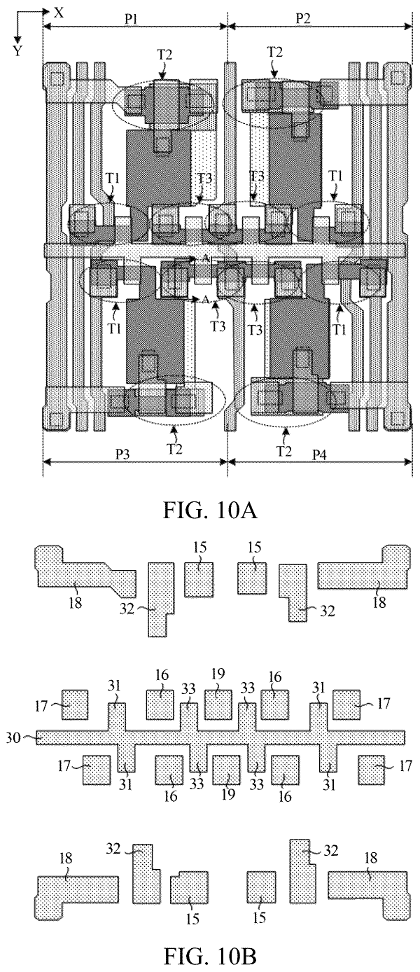

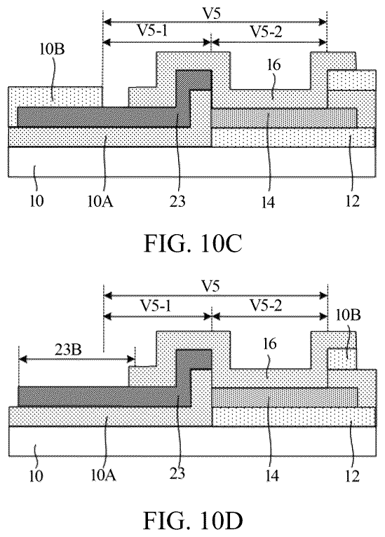

As shown in FIG. 10C, the display substrate may include a first conductive layer disposed on the base substrate 10 and a second conductive layer disposed on a side of the first conductive layer away from the base substrate. The first conductive layer may include at least a second connection electrode 12 disposed on the base substrate 10. The second conductive layer may include at least a fourth connection electrode 14 disposed on the second connection electrode 12, and the fourth connection electrode 14 is directly lapped with the second connection electrode 12.

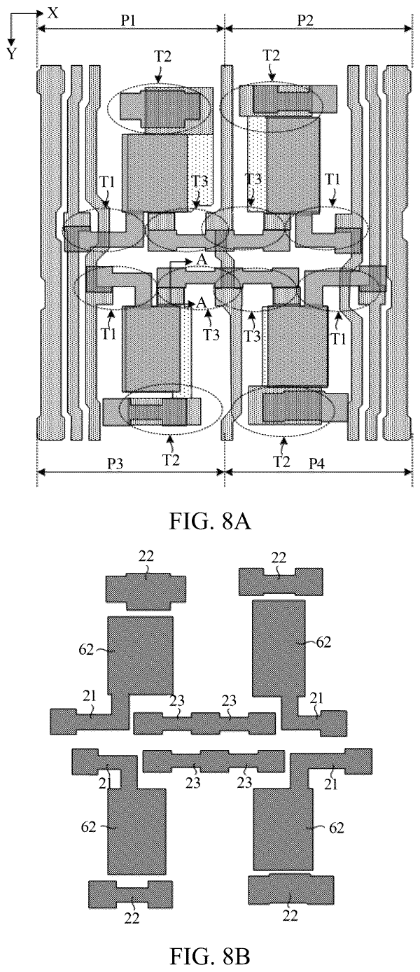

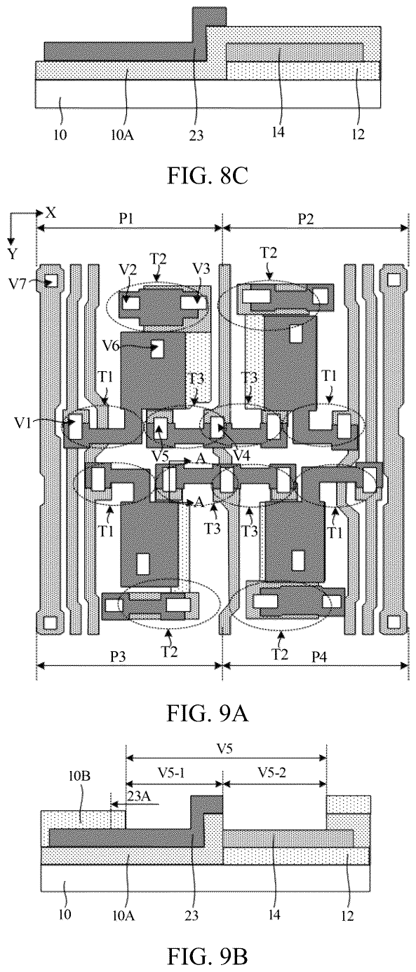

(103) A pattern of a semiconductor layer is formed. In an exemplary implementation mode, forming the pattern of the semiconductor layer may include: sequentially depositing a first insulation thin film and a semiconductor thin film on the base substrate on which the aforementioned patterns are formed, patterning the semiconductor thin film through a patterning process, forming a first insulation layer covering both the first conductive layer and the second conductive layer, and a semiconductor layer disposed on the first insulation layer, as shown in FIGS. 8A, 8B, and 8C, wherein FIG. 8B is a schematic diagram of the semiconductor layer in FIG. 8A, and FIG. 8C is a cross-sectional view taken along an A-A direction in FIG. 8A.

In an exemplary implementation mode, the semiconductor layer of each sub-pixel in the display substrate may include at least a first active layer 21 as an active layer of a first transistor T1, a second active layer 22 as an active layer of a second transistor T2, a third active layer 23 as an active layer of a third transistor T3, and a second electrode plate 62 as an intermediate electrode plate of a storage capacitor.

In an exemplary implementation mode, for the first sub-pixel P1 and the second sub-pixel P2, a first active layer 21 and a third active layer 23 may be disposed on one side of a first electrode plate 61 of a present sub-pixel in the second direction Y, a second active layer 22 may be disposed on a side of the first electrode plate 61 of the present sub-pixel in an opposite direction of the second direction Y, and an orthographic projection of the second active layer 22 on the base substrate is at least partially overlapped with an orthographic projection of a third connection electrode 13 of the present sub-pixel on the base substrate. A third active layer 23 of the first sub-pixel P1 may be disposed on a side of a first active layer 21 of a present sub-pixel in the first direction X, and a third active layer 23 of the second sub-pixel P2 may be disposed on a side of a first active layer 21 of a present sub-pixel in an opposite direction of the first direction X.

In an exemplary implementation mode, for the third sub-pixel P3 and the fourth sub-pixel P4, a first active layer 21 and a third active layer 23 may be disposed on a side of a first electrode plate 61 of a present sub-pixel in the opposite direction of the second direction Y, a second active layer 22 may be disposed on a side of the first electrode plate 61 of the present sub-pixel in the second direction Y, and an orthographic projection of the second active layer 22 on the base substrate is at least partially overlapped with an orthographic projection of a third connection electrode 13 of the present sub-pixel on the base substrate. A third active layer 23 of the third sub-pixel P3 may be disposed on a side of a first active layer 21 of a present sub-pixel in the first direction X, and a third active layer 23 of the fourth sub-pixel P4 may be disposed on a side of a first active layer 21 of a present sub-pixel in an opposite direction of the first direction X.

In an exemplary implementation mode, a second active layer 22 of the first sub-pixel P1 and a second active layer 22 of the second sub-pixel P2 are of an interconnected integral structure, and a second active layer 22 of the third sub-pixel P3 and a second active layer 22 of the fourth sub-pixel P4 are of an interconnected integral structure. By setting that second transistors of two adjacent sub-pixels in a pixel column share a source in the present disclosure, not only space is saved, but also a via connection structure is reduced and a preparation process is simplified.

In an exemplary implementation mode, an orthographic projection of a second active layer 22 on the base substrate is at least partially overlapped with an orthographic projection of a third connection electrode 13 on the base substrate, so that a first electrode plate 61 as a shielding layer may shield a channel region of a second transistor T2, avoid an influence of light on a channel, and ensure electrical performance of the second transistor T2.

In an exemplary implementation mode, an active layer of each transistor may include a first region, a second region, and a channel region located between the first region and the second region.

In an exemplary implementation mode, a first region of a first active layer 21 is adjacent to a corresponding data signal line 52, and a second region of the first active layer 21 is connected with a second electrode plate 62.

In an exemplary implementation mode, an orthographic projection of a first region of a second active layer 22 on the base substrate is not overlapped with an orthographic projection of a third connection electrode 13 on the base substrate, and orthographic projections of a second region and a channel region of the second active layer 22 on the base substrate are at least partially overlapped with the orthographic projection of the third connection electrode 13 on the base substrate.

In an exemplary implementation mode, a first region of a third active layer 23 is adjacent to a compensation signal line 53, and a second region of the third active layer 23 is adjacent to a fourth connection electrode 14.

In an exemplary implementation mode, for a first active layer 21, a second active layer 22, and a third active layer 23, positions of three active layers in the first sub-pixel P1 and positions of three active layers in the third sub-pixel P3 may be substantially mirror-symmetrical with respect to a vertical reference line, positions of three active layers in the second sub-pixel P2 and positions of three active layers in the fourth sub-pixel P4 may be substantially mirror-symmetrical with respect to the vertical reference line, the positions of the three active layers in the first sub-pixel P1 and the positions of the three active layers in the fourth sub-pixel P4 may be substantially mirror-symmetrical with respect to a horizontal reference line, and the positions of the three active layers in the second sub-pixel P2 and the positions of the three active layers in the third sub-pixel P3 may be substantially mirror-symmetrical with respect to the horizontal reference line.

In an exemplary implementation mode, a second electrode plate 62 may have a rectangular shape. Corners of the rectangular shape may be provided with chamfers. The second electrode plate 62 may be disposed between a second active layer 22 and a third active layer 23 of a present sub-pixel. An orthographic projection of a second electrode plate 62 on the base substrate is at least partially overlapped with an orthographic projection of a first electrode plate 61 on the base substrate. The second electrode plate 62 may be used as a transparent intermediate electrode plate of a transparent storage capacitor, and the first electrode plate 61 and the second electrode plate 62 form a transparent first capacitor.

In an exemplary implementation mode, the second electrode plate 62 and the second active layer 21 may be of an interconnected integral structure.

In an exemplary implementation mode, the semiconductor layer may be made of a metal oxide such as an oxide containing indium and tin, an oxide containing tungsten and indium, an oxide containing tungsten, indium, and zinc, an oxide containing titanium and indium, an oxide containing titanium, indium, and tin, an oxide containing indium and zinc, an oxide containing silicon, indium, and tin, and an oxide containing indium, gallium, and zinc. The semiconductor layer may be a single layer, a double-layer, or a multi-layer.

In an exemplary implementation mode, an area of a second electrode plate 62 in each sub-pixel may be substantially the same, so that a capacity of a storage capacitor in each sub-pixel is substantially the same.

In an exemplary implementation mode, positions of respective patterns in a semiconductor layer in the first sub-pixel P1 and positions of respective patterns in a semiconductor layer in the third sub-pixel P3 may be substantially mirror-symmetrical with respect to a horizontal reference line, positions of respective patterns in a semiconductor layer in the second sub-pixel P2and positions of respective patterns in a semiconductor layer in the fourth sub-pixel P4 may be substantially mirror-symmetrical with respect to the horizontal reference line, the positions of the respective patterns in the semiconductor layer in the first sub-pixel P1 and the positions of the respective patterns in the semiconductor layer in the second sub-pixel P2 may be substantially mirror-symmetrical with respect to a vertical reference line, and the positions of the respective patterns in the semiconductor layer in the third sub-pixel P3 and the positions of the respective patterns in the semiconductor layer in the fourth sub-pixel P4 may be substantially mirror-symmetrical with respect to the vertical reference line.

As shown in FIG. 8C, the display substrate may include at least a first conductive layer disposed on the base substrate 10, a second conductive layer disposed on a side of the first conductive layer away from the base substrate, a first insulation layer 10A disposed on a side of the second conductive layer away from the base substrate, and a semiconductor layer disposed on a side of the first insulation layer 10A away from the base substrate.

In an exemplary implementation mode, the first insulation layer 10A covers the second conductive layer, the first conductive layer in a region other than the second conductive layer, and the base substrate 10, and the semiconductor layer may at least include a third active layer 23 disposed on the first insulation layer 10A.

(104) A pattern of a second insulation layer is formed. In an exemplary implementation mode, forming the pattern of the second insulation layer may include: depositing a second insulation thin film on the base substrate on which the aforementioned patterns are formed, and patterning the second insulation thin film through a patterning process to form the pattern of the second insulation layer covering the semiconductor layer, wherein a plurality of vias are disposed on the second insulation layer, as shown in FIGS. 9A and 9B, wherein FIG. 9B is a cross-sectional view taken along an A-A direction in FIG. 9A.

In an exemplary implementation mode, a plurality of vias of each sub-pixel in the display substrate include at least: a first via V1, a second via V2 a third via V3, a fourth via V4, a fifth via V5, a sixth via V6, and a seventh via V7.

In an exemplary implementation mode, an orthographic projection of the first via V1 on the base substrate is within a range of orthographic projections of a first region of the first active layer 21 and a data signal line 52 on the base substrate. The first via V1 is a via of an adapter structure and includes two half holes. The second insulation layer in a shallow half hole is etched away to expose a surface of the first region of the first active layer 21, and the first insulation layer and the second insulation layer in a deep half hole are etched away to expose a surface of the data signal line 52, so that the via of the adapter structure composed of the two half holes simultaneously exposes the first region of the first active layer 21 and the data signal line 52. The first via V1 is configured such that a seventh connection electrode to be formed subsequently is simultaneously connected with the first region of the first active layer 21 and the data signal line 52 through the via.

In an exemplary implementation mode, an orthographic projection of the second via V2 on the base substrate is within a range of an orthographic projection of a first region of the second active layer 22 on the base substrate, the first insulation layer and the second insulation layer in the second via V2 are etched away to expose a surface of the first region of the second active layer 22, and the second via V2 is configured such that an eighth connection electrode to be formed subsequently is connected with the first region of the second active layer 22 through the via.

In an exemplary implementation mode, an orthographic projection of the third via V3 on the base substrate is within a range of orthographic projections of a second region of the second active layer 22 and a third connection electrode 13 on the base substrate. The third via V3 is a via of an adapter structure and includes two half holes. The second insulation layer in a shallow half hole is etched away to expose a surface of the second region of the second active layer 22, and the first insulation layer and the second insulation layer in a deep half hole are etched away to expose a surface of the third connection electrode 13, so that the via of the adapter structure composed of the two half holes simultaneously exposes the second region of the second active layer 22 and the third connection electrode 13. The third via V3 is configured such that a fifth connection electrode to be formed subsequently is simultaneously connected with the second region of the second active layer 22 and the third connection electrode 13 through the via.

In an exemplary implementation mode, an orthographic projection of the fourth via V4 on the base substrate is within a range of orthographic projections of a first region of the third active layer 23 and a compensation signal line 53 on the base substrate. The fourth via V4 is a via of an adapter structure and includes two half holes. The second insulation layer in a shallow half hole is etched away to expose a surface of the first region of the third active layer 23, and the first insulation layer and the second insulation layer in a deep half hole are etched away to expose a surface of the compensation signal line 53, so that the via of the adapter structure composed of the two half holes simultaneously exposes the first region of the third active layer 23 and the compensation signal line 53. The fourth via V4 is configured such that a ninth connection electrode to be formed subsequently is simultaneously connected with the first region of the third active layer 23 and the compensation signal line 53 through the via.

In an exemplary implementation mode, an orthographic projection of the fifth via V5 on the base substrate is within a range of orthographic projections of a second region of the third active layer 23 and a fourth connection electrode 14 on the base substrate. The fifth via V5 is a via of an adapter structure and includes two half holes. The second insulation layer in a shallow half hole is etched away to expose a surface of the second region of the third active layer 23. The first insulation layer and the second insulation layer in a deep half hole are etched away to expose a surface of the fourth connection electrode 14, so that the via of the adapter structure composed of the two half holes simultaneously exposes the second region of the third active layer 23 and the fourth connection electrode 14. The fifth via V5 is configured such that a sixth connection electrode to be formed subsequently is simultaneously connected with the second region of the third active layer 23 and the fourth connection electrode 14 through the via.

In an exemplary implementation mode, an orthographic projection of the six via V6 on the base substrate is within a range of an orthographic projection of a second electrode plate 62 on the base substrate. The first insulation layer and the second insulation layer in the six via V6 are etched away to expose a surface of the second electrode plate 62. The six via V6 is configured such that a second gate electrode to be formed subsequently is connected with the second electrode plate 62 through the via.

In an exemplary implementation mode, an orthographic projection of the seventh via V7 on the base substrate is within a range of an orthographic projection of a first power supply line 51 on the base substrate. The first insulation layer and the second insulation layer in the seventh via V7 are etched away to expose a surface of the first power supply line 51. The seventh via V7 is configured such that an eighth connection electrode to be formed subsequently is connected with the first power supply line 51 through the via.

As shown in FIG. 9B, the display substrate may include at least a first conductive layer disposed on the base substrate 10, a second conductive layer disposed on a side of the first conductive layer away from the base substrate, a first insulation layer 10A disposed on a side of the second conductive layer away from the base substrate, a semiconductor layer disposed on a side of the first insulation layer 10A away from the base substrate, and a second insulation layer 10B disposed on a side of the semiconductor layer away from the base substrate.

In an exemplary implementation mode, the second insulation layer 10B covers the third active layer 23, and the first insulation layer 10A exposed in a region other than the third active layer 23. The second insulation layer 10B includes at least a fifth via V5 of an adapter structure. The fifth via V5 may include at least two half holes: a shallow half hole V5-1 and a deep half hole V5-2, wherein the second insulation layer 10B in the shallow half hole V5-1 is removed to expose a surface of the third active layer 23 in the semiconductor layer, and the second insulation layer 10B and the first insulation layer 10A in the deep half hole V5-2 are removed to expose a surface of a fourth connection electrode 14 in the second conductive layer.

In an exemplary implementation mode, in a process of forming a pattern of a second insulation layer, a plurality of vias are formed using a dry etching process while a first conductorization process is performed on a semiconductor layer exposed in the vias. In the first conductorization process, edge portions of the semiconductor layer covered by the second insulation layer close to the vias are also conductorized, that is, the semiconductor layer after the first conductorization process extends toward directions away from the vias to form a first conductorized region 23 A.

(105) A pattern of a third conductive layer is formed. In an exemplary implementation mode, forming the pattern of the third conductive layer may include: depositing a third conductive thin film on the base substrate on which the aforementioned patterns are formed, patterning the third conductive thin film through a patterning process, and forming a pattern of a third conductive layer on the second insulation layer, as shown in FIGS. 10A, 10B, 10C, and 10D, wherein FIG. 10B is a schematic diagram of the third conductive layer in FIG. 10A, and FIGS. 10C and 10D are cross-sectional views taken along an A-A direction in FIG. 10A.

In an exemplary implementation mode, a third conductive layer of a repetition unit in the display substrate may include one scan signal line 30. The third conductive layer of each sub-pixel in the display substrate may include at least a fifth connection electrode 15, a sixth connection electrode 16, a seventh connection electrode 17, an eighth connection electrode 18, a ninth connection electrode 19, a first gate electrode 31, a second gate electrode 32, and a third gate electrode 33.

In an exemplary implementation mode, a main body portion of the scan signal line 30 extends along the first direction X and may be disposed in a middle of the repetition unit in the second direction Y, i.e., located between, the first sub-pixel P1 and the second sub-pixel P2, and the third sub-pixel P3 and the fourth sub-pixel P4. The scan signal line 30 is configured to simultaneously control turn-on or turn-off of all first transistors T1 and all third transistors T3 in four sub-pixels of the repetition unit.

In an exemplary implementation mode, the first gate electrode 31 may have a shape of a strip extending along the second direction Y, and may be disposed on a side of the scan signal line 30 close to the first active layer 21. A first end of the first gate electrode 31 is connected with the scan signal line 30, and a second end of the first gate electrode 31 extends along a direction towards the first active layer 21. An orthographic projection of the first gate electrode 31 on the base substrate is at least partially overlapped with an orthographic projection of the first active layer 21 on the base substrate. In an exemplary implementation mode, the first gate electrode 31 may serve as a gate electrode of a first transistor T1, so that the scan signal line 30 may control turn-on or turn-off of the first transistor T1.

In an exemplary implementation mode, the second gate electrode 32 may have a shape of a strip extending along the first direction X. A first end of the second gate electrode 32 is connected with the second electrode plate 62 through the sixth via V6, and a second end of the second gate electrode 32 extends along a direction towards the second active layer 22. An orthographic projection of the second gate electrode 32 on the base substrate is at least partially overlapped with an orthographic projection of the second active layer 22 on the base substrate. In an exemplary implementation mode, the second gate electrode 32 may serve as a gate electrode of a second transistor T2 and may control turn-on or turn-off of the second transistor T2.

In the exemplary implementation mode, since the second gate electrode 32 is connected with the second electrode plate 62, and the second electrode plate 62 is connected with the first region of the first active layer 21, it is achieved that a second electrode of the first transistor T1, a gate electrode of the second transistor T2 and the second electrode plate 62 have a same potential, so that the second electrode plate 62 has a potential of a first node in a pixel drive circuit.

In an exemplary implementation mode, the third gate electrode 33 may have a shape of a strip extending along the second direction Y, and may be disposed on a side of the scan signal line 30 close to the third active layer 23. A first end of the third gate electrode 33 is connected with the scan signal line 30, a second end of the third gate electrode 33 extends along a direction towards the third active layer 23, and an orthographic projection of the third gate electrode 33 on the base substrate is at least partially overlapped with an orthographic projection of the third active layer 23 on the base substrate. In an exemplary implementation mode, the third gate electrode 33 may serve as a gate electrode of a third transistor T3, so that the scan signal line 30 may control turn-on or turn-off of the third transistor T3.

In an exemplary implementation mode, in one sub-pixel, one scan signal line 30 is simultaneously connected with the first gate electrode 31 and the third gate electrode 33, so that the scan signal line 30 may control turn-on or turn-off of a first transistor T1 and a third transistor T3 in one sub-pixel.

In an exemplary implementation mode, in one pixel row, one scan signal line 30 is simultaneously connected with all first gate electrodes 31 and all third transistors 33 in a plurality of sub-pixels, so that the scan signal line 30 may control turn-on or turn-off of all first transistors T1 and all third transistors T3 in one pixel row.

In an exemplary implementation mode, in one repetition unit, one scan signal line 30 is simultaneously connected with all first gate electrodes 31 and all third transistors 33 in a plurality of sub-pixels, so that the scan signal line 30 may simultaneously control turn-on or turn-off of all first transistors T1 and all third transistors T3 in the repetition unit.

In an exemplary implementation mode, the fifth connection electrode 15 may have a rectangular shape, may be disposed on a side of the second electrode plate 62 away from the scan signal line 30, and the fifth connection electrode 15 is simultaneously connected with the second region of the second active layer 22 and the third connection electrode 13 through the third via V3.

In an exemplary implementation mode, since the fifth connection electrode 15 is simultaneously connected with the second region of the second active layer 22 and the third connection electrode 13, the third connection electrode 13 is connected with the first connection electrode 11, and the first connection electrode 11 is connected with the first electrode plate 61, the fifth connection electrode 15 enables a second electrode of a second transistor and the first electrode plate 61 to have a same potential. In an exemplary implementation mode, the fifth connection electrode 15 is configured to be connected with a tenth connection electrode to be formed subsequently.

In an exemplary implementation mode, the sixth connection electrode 16 may have a rectangular shape and may be disposed on a side of the second electrode plate 62 close to the scan signal line 30, and the sixth connection electrode 16 is simultaneously connected with the second region of the third active layer 23 and the fourth connection electrode 14 through the fifth via V5.

In an exemplary implementation mode, since the sixth connection electrode 16 is simultaneously connected with the second region of the third active layer 23 and the fourth connection electrode 14, the fourth connection electrode 14 is connected with the second connection electrode 12, and the second connection electrode 12 is connected with the first electrode plate 61, the sixth connection electrode 16 enables a second electrode of a third transistor and the first electrode plate 61 to have a same potential.

In an exemplary implementation mode, the fifth connection electrode 15 and the sixth connection electrode 16 achieve a connection between the second electrode of the second transistor, the second electrode of the third transistor, and the first electrode plate 61, so that the fifth connection electrode 15 and the first electrode plate 61 have a potential of a second node in the pixel drive circuit.

In an exemplary implementation mode, the seventh connection electrode 17 may have a rectangular shape and may be disposed between the first gate electrode 31 and the first power supply line 51, and the seventh connection electrode 17 is simultaneously connected with the first region of the first active layer 21 and the data signal line 52 through the first via V1, thereby achieving that a data signal is written into the first electrode of the first transistor T1 by the data signal line 52. In an exemplary implementation mode, each data signal line 52 may be connected with a first region of a first active layer in one sub-pixel through the first via V1, thereby achieving that data signals are written into four first transistors T1 in one repetition unit by four data signal lines 52, respectively.

In an exemplary implementation mode, the four data signal lines 52 may include a first data signal line, a second data signal line, a third data signal line, and a fourth data signal line. The first data signal line may be located on a side of a first power supply line 51 in a first pixel column in the first direction X, and may be connected with a first region of a first active layer in a first sub-pixel P1. The second data signal line may be located on a side of the first data signal line in the first direction X, and may be connected with a first region of a first active layer in a third sub-pixel P3. The third data signal line may be located on a side of a compensation signal line 53 in the first direction X, and may be connected with a first region of a first active layer in a second sub-pixel P2. The fourth data signal line may be located on a side of the third data signal line in the first direction X, and may be connected with a first region of a first active layer in a fourth sub-pixel P4.

In an exemplary implementation mode, the eighth connection electrode 18 may have a shape of a strip extending along the first direction X and may be disposed on a side of the second electrode plate 62 away from the scan signal line 30. A first end of the eighth connection electrode 18 is connected with the first power supply line 51 through the seventh via V7, and a second end of the eighth connection electrode 18 is connected with the first region of the second active layer 22 through the second via V2, thereby achieving that a first power supply signal is written into the first electrode of the second transistor T2 by the first power supply line 51.

In an exemplary implementation mode, a first power supply line 51 of a first pixel column may simultaneously supply a first power supply signal to pixel drive circuits in a first sub-pixel P1 and a third sub-pixel P3, and a first power supply line 51 of a second pixel column may simultaneously supply a first power supply signal to pixel drive circuits in a second sub-pixel P2 and a fourth sub-pixel P4, therefore a first power supply line 51 in one repetition unit has a one-drag-two structure. In the display substrate according to the present disclosure, a first power supply line is designed to have a one-drag-two structure, which saves a quantity of signal lines, reduces occupied space, has a simple structure and a reasonable layout, makes full use of layout space, improves a space utilization rate, and is beneficial to improving a resolution and transparency.

In an exemplary implementation mode, two first power supply lines 51 in one repetition unit are symmetrically disposed with respect to a compensation signal line 53, and a second transistor T2 of the first pixel column and a second transistor T2 of the second pixel column are symmetrically disposed with respect to the compensation signal line 53. This symmetrical structure according to the present disclosure may ensure that a voltage drop of a first power supply line written into a second transistor T2 is substantially the same, ensuring display uniformity.

In an exemplary implementation mode, the ninth connection electrode 19 may have a rectangular shape, and may be disposed between third gate electrodes 33 of two adjacent sub-pixels in the first direction X, and the ninth connection electrode 19 is simultaneously connected with the first region of the third active layer 23 and the compensation signal line 53 through the fourth via V4, thereby achieving that a compensation signal is written into a first electrode of a third transistor T3 by the compensation signal line 53.

In an exemplary implementation mode, the compensation signal line 53 may simultaneously supply a compensation signal to a pixel drive circuit in each sub-pixel so that four pixel drive circuits in one repetition unit may share one compensation signal line 53, i.e., the compensation signal line 53 in one repetition unit has a one-drag-four structure. In the display substrate according to the present disclosure, a compensation signal line is designed to have a one-drag-four structure, which saves a quantity of signal lines, reduces occupied space, has a simple structure and a reasonable layout, makes full use of layout space, improves a space utilization rate, and is beneficial to improving a resolution and transparency.

In an exemplary implementation mode, the compensation signal line 53 is disposed between the first pixel column and the second pixel column, and a third transistor T3 of the first pixel column and a third transistor T3 of the second pixel column are symmetrically disposed with respect to the compensation signal line 53. This symmetrical structure according to the present disclosure may ensure that a Resistor-Capacitor (RC) delay of a compensation signal written into a third transistor T3 is substantially the same, ensuring display uniformity.

In an exemplary implementation mode, positions of respective patterns in a third conductive layer in the first sub-pixel P1 and positions of respective patterns in a third conductive layer in the third sub-pixel P3 may be substantially mirror-symmetrical with respect to a horizontal reference line, positions of respective patterns in a third conductive layer in the second sub-pixel P2and positions of respective patterns in a third conductive layer in the fourth sub-pixel P4 may be substantially mirror-symmetrical with respect to the horizontal reference line, the positions of the respective patterns in the third conductive layer in the first sub-pixel P1 and the positions of the respective patterns in the third conductive layer in the second sub-pixel P2 may be substantially mirror-symmetrical with respect to a vertical reference line, and the positions of the respective patterns in the third conductive layer in the third sub-pixel P3 and the positions of the respective patterns in the third conductive layer in the fourth sub-pixel P4 may be substantially mirror-symmetrical with respect to the vertical reference line.

FIGS. 10C and 10D illustrate a structure in which the sixth connection electrode 16 is simultaneously connected with the second region of the third active layer 23 and the fourth connection electrode 14 through a via of an adapter structure. The display substrate may include at least a first conductive layer disposed on the base substrate 10, a second conductive layer disposed on a side of the first conductive layer away from the base substrate, a first insulation layer 10A disposed on a side of the second conductive layer away from the base substrate, a semiconductor layer disposed on a side of the first insulation layer 10A away from the base substrate, a second insulation layer 10B disposed on a side of the semiconductor layer away from the base substrate, and a third conductive layer disposed on a side of the second insulation layer 10B away from the base substrate.

In an exemplary implementation mode, the first conductive layer may at least include a second connection electrode 12 disposed on the base substrate 10, and the second conductive layer may include at least a fourth connection electrode 14 disposed on the second connection electrode 12, the fourth connection electrode 14 is directly lapped with the second connection electrode 12. The first insulation layer 10A covers the fourth connection electrode 14, the base substrate 10 exposed in a region other than the fourth connection electrode 14, and the second connection electrode 12. The semiconductor layer may at least include a third active layer 23 disposed on the first insulation layer 10A. The second insulation layer 10B covers the third active layer 23, and the first insulation layer 10A exposed in a region other than the third active layer 23. The third conductive layer may at least include a sixth connection electrode 16 disposed on the second insulation layer 10B. The sixth connection electrode 16 is simultaneously connected with the third active layer 23 and the fourth connection electrode 14 through a fifth via V5 of an adapter structure.

In an exemplary implementation mode, in a process of forming the pattern of the third conductive layer, a wet etching process is first adopted to form the pattern of the third conductive layer, so that at least one connection electrode is simultaneously connected with the second conductive layer and the semiconductor layer through a via of an adapter structure. A fifth via V5 of a via structure of an adapter structure may include at least two half holes: a shallow half hole V5-1 and a deep half hole V5-2, wherein the second insulation layer 10B in the shallow half hole V5-1 is removed to expose a surface of the third active layer 23 in the semiconductor layer, and the second insulation layer 10B and the first insulation layer 10A in the deep half hole V5-2 are removed to expose a surface of the fourth connection electrode 14 in the second conductive layer, thereby achieving that the sixth connection electrode 16 is simultaneous connected with the third active layer 23 and the fourth connection electrode 14 through the shallow half hole V5-1 and the deep half hole V5-2. In an exemplary implementation mode, a distance is provided between an end of the sixth connection electrode 16 located in a region of the shallow half hole V5-1 and an edge of the shallow half hole V5-1, that is, the sixth connection electrode 16 does not fully cover the shallow half hole V5-1, as shown in FIG. 10C.

In an exemplary implementation mode, after the pattern of the third conductive layer is formed through the wet etching process, a self-alignment process using the third conductive layer as a mask is used, the second insulation layer in a region other than the third conductive layer is etched by using a dry etching process, and second conductorization is performed on the exposed semiconductor layer while etching off the second insulation layer, to form a second conductorized region 23B, as shown in FIG. 10D.

In an exemplary implementation mode, during a second conductorization process, an edge portion of the semiconductor layer covered by the third conductive layer is also conductorized, i.e., the semiconductor layer after the second conductorization extends to a first conductorized region, and a twice conductorized region is formed in an overlapping region of the first conductorized region and a second conductorized region, so that a reliable connection between the third conductive layer and the semiconductor layer may be ensured.

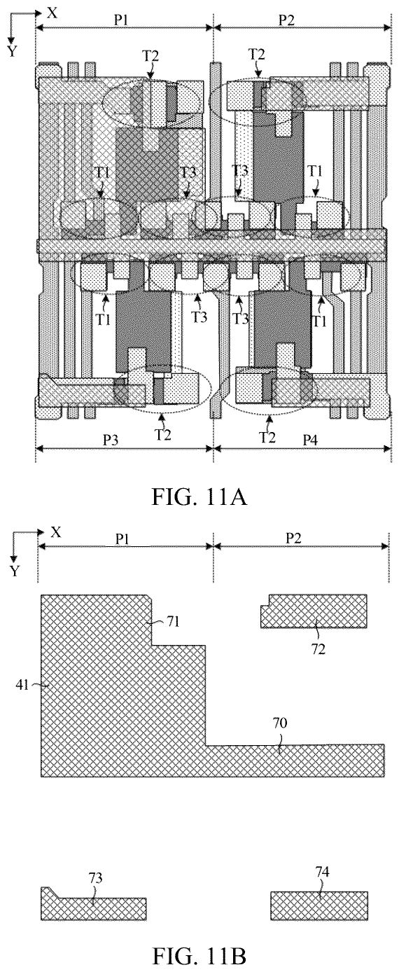

(106) Patterns of a third insulation layer and a red color film layer are formed. In an exemplary implementation mode, forming the patterns of the third insulation layer and the red color film layer may include: first depositing a third insulation thin film on the base substrate on which the aforementioned patterns are formed, to form a third insulation layer covering the aforementioned patterns. Subsequently, a red color film thin film is coated, and the red color film thin film is patterned through a patterning process to form a pattern of a red color film layer on a planarization layer, as shown in FIGS. 11A and 11B, wherein FIG. 11B is a schematic diagram of the red color film layer in FIG. 11A.

In an exemplary implementation mode, the red color film layer in one repetition unit in the display substrate may include a red filter 41, a shielding strip 70, a first shielding block 71, a second shielding block 72, a third shielding block 73, and a fourth shielding block 74.

In an exemplary implementation mode, the red filter 41 may have a rectangular shape and may be disposed in the first sub-pixel P1. The red filter 41 is configured to enable the first sub-pixel P1 to emit red light.

In an exemplary implementation mode, the shielding strip 70 may have a shape of a strip extending along the first direction X, may be disposed in a middle of the repetition unit in the second direction Y, i.e., located between, the first sub-pixel Pl and the second sub-pixel P2, and the third sub-pixel P3 and the fourth sub-pixel P4. An orthographic projection of the shielding strip 70 on the base substrate is at least partially overlapped with an orthographic projection of the scan signal line 30 on the base substrate, to shield the scan signal line 30.

In an exemplary implementation mode, the first shielding block 71 may have a shape of a strip extending along the first direction X and may be disposed in the first sub-pixel P1. An orthographic projection of the first shielding block 71 on the base substrate is at least partially overlapped with an orthographic projection of a second transistor T2 in the first sub-pixel Pl on the base substrate, to shield the second transistor T2 in the first sub-pixel P1.

In an exemplary implementation mode, the red filter 41, the shielding strip 70, and the first shielding block 71 may be of an interconnected integral structure.

In an exemplary implementation mode, the second shielding block 72 may have a shape of a strip extending along the first direction X and may be disposed in the second sub-pixel P2. An orthographic projection of the second shielding block 72 on the base substrate is at least partially overlapped with an orthographic projection of a second transistor T2 in the second sub-pixel P2 on the base substrate, to shield the second transistor T2 in the second sub-pixel P2. In an exemplary implementation mode, the third shielding block 73 may have a shape of a strip extending along the first direction X and may be disposed in the third sub-pixel P3. An orthographic projection of the third shielding block 73 on the base substrate is at least partially overlapped with an orthographic projection of a second transistor T2 in the third sub-pixel P3 on the base substrate, to shield the second transistor T2 in the third sub-pixel P3.

In an exemplary implementation mode, the fourth shielding block 74 may have a shape of a strip extending along the first direction X and may be disposed in the fourth sub-pixel P4. An orthographic projection of the fourth shielding block 74 on the base substrate is at least partially overlapped with an orthographic projection of a second transistor T2 in the fourth sub-pixel P4 on the base substrate, to shield the second transistor T2 in the fourth sub-pixel P4.

In an exemplary implementation mode, in the present disclosure, second transistors T2 of four sub-pixels are shielded by using the red color film layer, which may improve a shielding effect and effectively ensure electrical performance of the second transistors T2.

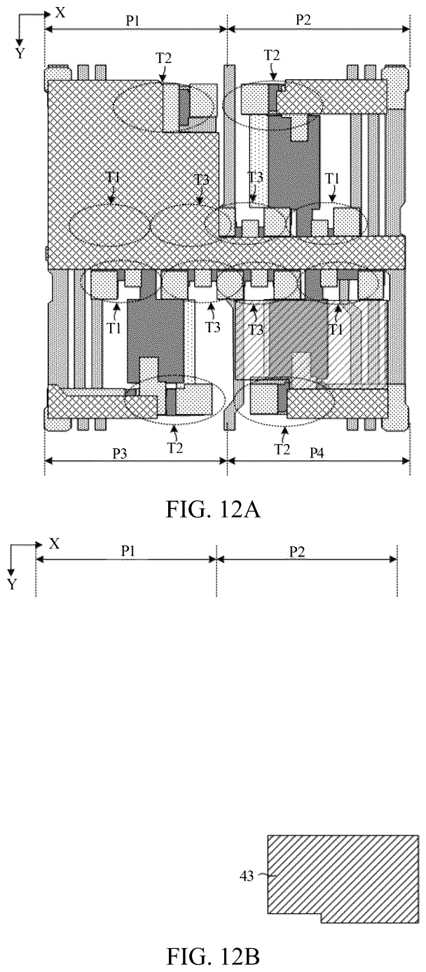

(107) A pattern of a green color film layer is formed. In an exemplary implementation mode, forming the pattern of the green color film layer may include: coating a green color film thin film on the base substrate on which the aforementioned patterns are formed, patterning the green color film thin film through a patterning process, to form the pattern of the green color film layer on the planarization layer, as shown in FIGS. 12A and 12B, wherein FIG. 12B is a schematic diagram of the green color film layer in FIG. 12A.

In an exemplary implementation mode, the green color film layer in one repetition unit in the display substrate may include a green filter 43.

In an exemplary implementation mode, the green filter 43 may have a rectangular shape, and may be disposed in the fourth sub-pixel P4. A groove may be disposed at a corner position close to the eleventh via V11. The green filter 43 is configured to enable the fourth sub-pixel P4 to emit green light.

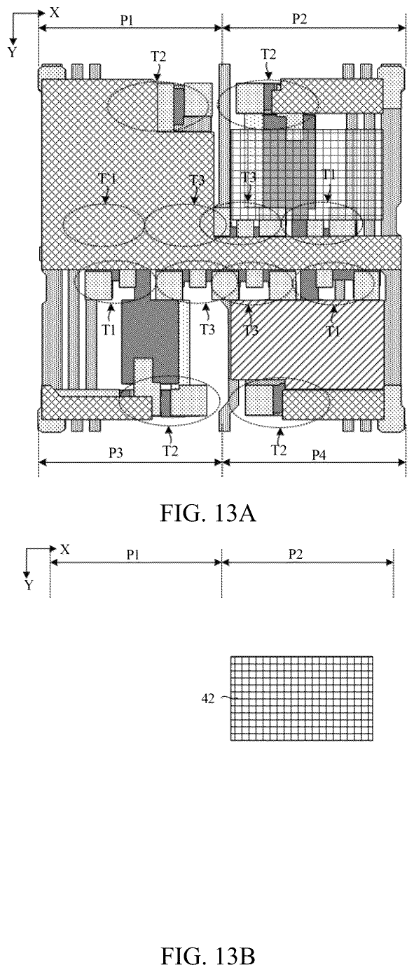

(108) A pattern of a blue color film layer is formed. In an exemplary implementation mode, forming the pattern of the blue color film layer may include: coating a blue color film thin film on the base substrate on which the aforementioned patterns are formed, patterning the blue color film thin film through a patterning process, to form the pattern of the blue color film layer on the planarization layer, as shown in FIGS. 13A and 13B, wherein FIG. 13B is a schematic diagram of the blue color film layer in FIG. 13A.

In an exemplary implementation mode, the blue color film layer in one repetition unit in the display substrate may include a blue filter 42.

In an exemplary implementation mode, the blue filter 42 may have a rectangular shape and may be disposed in the second sub-pixel P2. The blue filter 42 is configured to enable the second sub-pixel P2 to emit blue light.

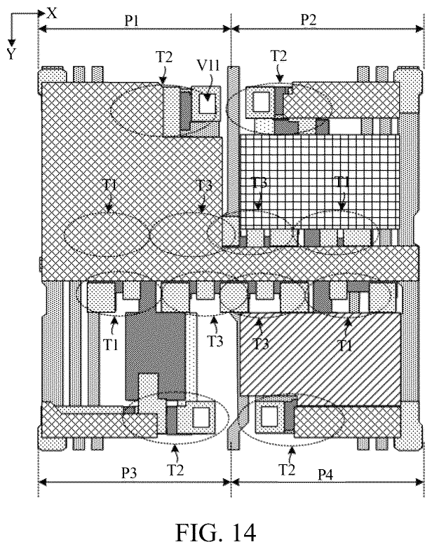

(109) A pattern of a planarization layer is formed. In an exemplary implementation mode, forming the pattern of the planarization layer may include: coating a planarization thin film on the base substrate on which the aforementioned patterns are formed, patterning the planarization thin film and a third insulation thin film through a patterning process, forming the pattern of the planarization layer covering the color film structure layer, wherein the planarization layer is provided with a plurality of vias, as shown in FIG. 14.

In an exemplary implementation mode, a via of each sub-pixel at least includes an eleventh via V11.

In an exemplary implementation mode, an orthographic projection of the eleventh via V11 on the base substrate is located within a range of an orthographic projection of the fifth connection electrode 15 on the base substrate. The third insulation layer and the planarization layer in the eleventh via V11 are etched away to expose a surface of the fifth connection electrode 15, and the eleventh via V11 is configured such that a tenth connection electrode to be formed subsequently is connected with the fifth connection electrode 15 through the via.

In an exemplary implementation mode, in this process, a one-time patterning process is adopted to simultaneously form vias on the third insulation layer and the planarization layer, i.e., the third insulation layer and the planarization layer share a one-time MASK process, effectively reducing times of patterning processes.

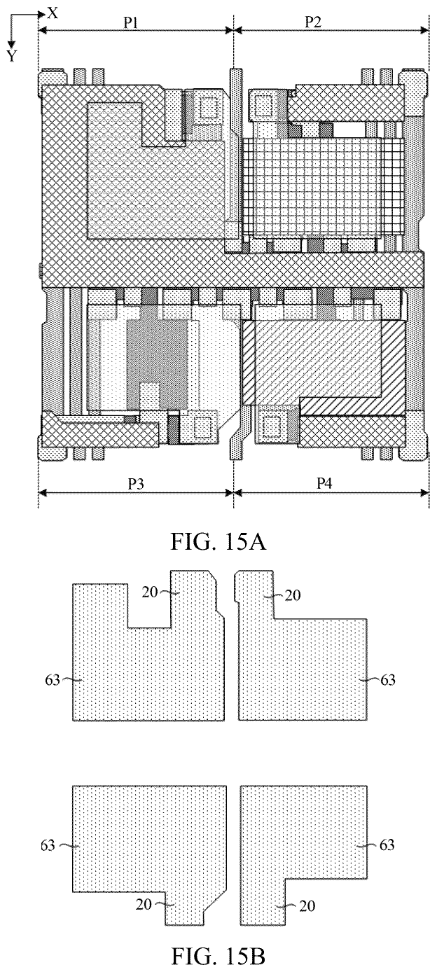

(110) A pattern of a fourth conductive layer is formed. In an exemplary implementation mode, forming the pattern of the fourth conductive layer may include: depositing a fourth conductive thin film on the base substrate on which the aforementioned patterns are formed, patterning the fourth conductive thin film through a patterning process to form the pattern of the fourth conductive layer on a color filter layer, as shown in FIG. 15A and FIG. 15B, wherein FIG. 15B is a schematic diagram of the fourth conductive layer in FIG. 15A.

In an exemplary implementation mode, the fourth conductive layer of each sub-pixel in the display substrate may include at least a tenth connection electrode 20 and a third electrode plate 63.

In an exemplary implementation mode, the third electrode plate 63 may have a rectangular shape. Corners of the rectangular shape may be provided with chamfers. An orthographic projection of the third electrode plate 63 on the base substrate is at least partially overlapped with an orthographic projection of the second electrode plate 62 on the base substrate. The third electrode plate 63 may serve as a transparent upper electrode plate of a transparent storage capacitor, and the third electrode plate 63 and the second electrode plate 62 form a transparent second capacitor. In an exemplary implementation mode, the third electrode plate 63 also serves as an anode of a light emitting device.

In an exemplary implementation mode, four third electrode plates 63 (anodes) in one repetition unit are arranged in a square. An upper left anode is connected with a pixel drive circuit in the first sub-pixel P1, an upper right anode is connected with a pixel drive circuit in the second sub-pixel P2, a lower left anode is connected with a pixel drive circuit in the third sub-pixel P3, and a lower right anode is connected with a pixel drive circuit in the fourth sub-pixel P4. In some possible implementation modes, an arrangement mode of the anodes may be adjusted according to actual needs, which is not specifically limited here in the present disclosure.

In the exemplary implementation mode, the tenth connection electrode 20 may have a rectangular shape and may be located on a side of the third electrode plate 63 away from the scan signal line 30. A first end of the tenth connection electrode 20 is connected with the third electrode plate 63. A second end of the tenth connection electrode 20 is connected with the fifth connection electrode 15 through the eleventh via V11 after extending toward a direction away from the scan signal line 30.

In an exemplary implementation mode, in at least one sub-pixel, the tenth connection electrode 20 and the third electrode plate 63 may be of an interconnected integral structure.

In an exemplary implementation mode, the first conductive layer may be made of a transparent conductive material, such as Indium Tin Oxide (ITO) or Indium Zinc Oxide (IZO). In an exemplary implementation mode, since the third electrode plate 63 is connected with the tenth connection electrode 20, the tenth connection electrode 20 is connected with the fifth connection electrode 15, the fifth connection electrode 15 is connected with the third connection electrode 13, the third connection electrode 13 is connected with the first connection electrode 11, and the first connection electrode 11 is connected with the first electrode plate 61, it is achieved that the first electrode plate 61 and the third electrode plate 63 have a potential of a second node in a pixel drive circuit. Since the second electrode plate 62 has a potential of a first node in the pixel drive circuit, the first electrode plate 61 having the potential of the second node and the second electrode plate 62 having the potential of the first node form a first capacitor, and the third electrode plate 63 having the potential of the second node and the second electrode plate 62 having the potential of the first node form a second capacitor, and the first capacitor and the second capacitor are connected in parallel. The first capacitor and the second capacitor in a parallel structure constitute a complete storage capacitor.

In the exemplary implementation mode, since the first electrode plate 61 and third electrode plate 63 are made of a transparent conductive material and the second electrode plate 62 is made of a transparent metal oxide, the storage capacitor is a transparent capacitor.

In the present disclosure, a first conductive layer of a transparent conductive material, a semiconductor layer of a transparent metal oxide, and a fourth conductive layer of a transparent conductive material are utilized to form a first capacitor and a second capacitor in a parallel structure, and the first capacitor and the second capacitor in the parallel structure constitute a complete storage capacitor. On one hand, a capacitance value of the storage capacitor may be effectively increased, and on the other hand, an area of an electrode plate may be reduced under a condition of ensuring the capacitance value of the storage capacitor, and an occupied area may be effectively reduced.

In an exemplary implementation mode, positions of respective patterns in a fourth conductive layer in the first sub-pixel P1 and positions of respective patterns in a fourth conductive layer in the third sub-pixel P3 may be substantially mirror-symmetrical with respect to a horizontal reference line, positions of respective patterns in a fourth conductive layer in the second sub-pixel P2and positions of respective patterns in a fourth conductive layer in the fourth sub-pixel P4 may be substantially mirror-symmetrical with respect to the horizontal reference line, the positions of the respective patterns in the fourth conductive layer in the first sub-pixel P1 and the positions of the respective patterns in the fourth conductive layer in the second sub-pixel P2 may be substantially mirror-symmetrical with respect to a vertical reference line, and the positions of the respective patterns in the fourth conductive layer in the third sub-pixel P3 and the positions of the respective patterns in the fourth conductive layer in the fourth sub-pixel P4 may be substantially mirror-symmetrical with respect to the vertical reference line.

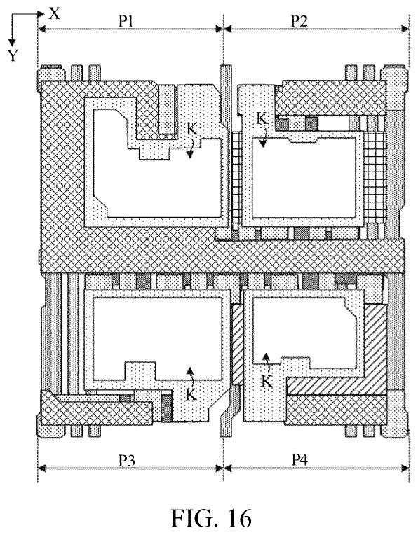

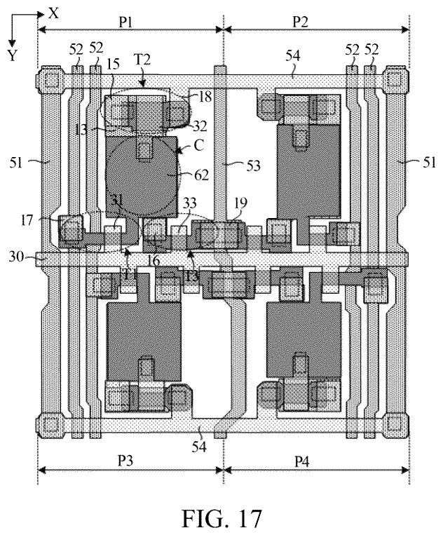

(111) A pixel definition layer is formed. In an exemplary implementation mode, forming a pattern of the pixel definition layer may include: coating a pixel definition thin film on the base substrate on which the aforementioned patterns are formed, and patterning the pixel definition thin film through a patterning process, to form the pixel definition layer, as shown in FIG. 16.

In an exemplary implementation mode, a pixel opening K is formed on the pixel definition layer of each sub-pixel in the display substrate, the pixel definition thin film in the pixel opening K is removed to expose a portion of a surface of the third electrode plate 63, and an orthographic projection of the pixel opening K on the base substrate is within a range of an orthographic projection of the third electrode plate 63 on the base substrate.

In an exemplary implementation mode, a shape of the pixel opening K may be similar to a shape of the third electrode plate 63 in a plane parallel to the base substrate, and a cross-sectional shape of the pixel opening K may be a rectangle, a trapezoid or the like in a plane perpendicular to the base substrate.

In an exemplary implementation mode, a shape of a pixel opening may include any one or more of following: a triangle, a rectangle, a trapezoid, a parallel four-frame shape, a five-frame shape, a six-frame shape, a circle, and an ellipse.

In an exemplary implementation mode, shapes of pixel openings of four sub-pixels may be the same or may be different. Areas of the pixel openings of the four sub-pixels may be the same or may be different.

In an exemplary implementation mode, shapes and areas of pixel openings of four sub-pixels may be different to accommodate transmittances of filters of different sub-pixels, so that light emitting devices of the four sub-pixels may emit light with same brightness at different currents, service lives of light emitting devices of the four sub-pixels are optimized to a maximum extent, and a product life is guaranteed.

In an exemplary implementation mode, the pixel definition layer may be made of polyimide, acrylic, or polyethylene terephthalate, etc.

(112) Patterns of an organic emitting layer and a cathode are formed. In an exemplary implementation mode, forming the patterns of the organic emitting layer and the cathode may include: forming a pattern of an organic emitting layer, wherein the organic emitting layer is connected with the third electrode plate 63 through the pixel opening K. Then, a cathode is formed, and the cathode is connected with the organic emitting layer.

In an exemplary implementation mode, the organic emitting layer may include an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, the organic emitting layer may be formed through evaporation using a Fine Metal Mask (FMM) or an Open Mask, or through an inkjet process.

(113) A pattern of an encapsulation layer is formed. In an exemplary implementation mode, forming the pattern of the encapsulation layer may include: depositing a first inorganic thin film using an open mask, so as to form a first encapsulation layer; then, inkjet printing an organic material on the first encapsulation layer by using an inkjet printing process, and curing to form a film to form a second encapsulation layer; and then, depositing a second inorganic thin film by using an open mask to form a third encapsulation layer. The first encapsulation layer, the second encapsulation layer, and the third encapsulation layer form the encapsulation layer. The first encapsulation layer and the third encapsulation layer may be made of any one or more of Silicon Oxide (SiOx), Silicon Nitride (SiNx), Silicon Carbide (SiC), Silicon Carbonitride (SiCN), and Silicon Oxynitride (SiON), and may be a single layer, a multi-layer, or a composite layer. The second encapsulation layer may be made of a resin material, thereby forming a stacked structure of an inorganic material/an organic material/an inorganic material, wherein an organic material layer is disposed between two inorganic material layers, thus ensuring that external water vapor cannot enter a light emitting structure layer.

In the exemplary implementation mode, thus, preparation of the display substrate of the embodiment is completed.

FIG. 17 is a schematic diagram of a structure of a drive circuit layer in another display substrate according to an exemplary embodiment of the present disclosure, illustrating a structure of a pixel drive circuit in one repetition unit (four sub-pixels) in a bottom emission display substrate. As shown in FIG. 17, a main body structure of the drive circuit layer in the display substrate of the embodiment is substantially the same as that of the foregoing embodiments, except that at least one repetition unit may include a power supply connection line 54, and the power supply connection line 54 is connected with a first power supply line 51 to form a mesh structure for transmitting a first power supply signal in a mesh shape.

In the exemplary implementation mode, structures and connection relationships of a fifth connection electrode 15 to a ninth connection electrode 19, a first gate electrode 31 to a third gate electrode 33, a scan signal line 30, the first power supply lines 51, a data signal lines 52, and a compensation signal line 53 are substantially the same as those of the foregoing embodiments, and will not be repeated here.

In an exemplary implementation mode, the third conductive layer of the embodiment may further include the power supply connection line 54, a shape of the power supply connection line 54 may be a line shape extending along the first direction X and may be respectively disposed in a first pixel row and a second pixel row, and the power supply connection line 54 is connected with the first power supply line 51 through a via, so that the power supply connection line 54 extending along the first direction X and the first power supply line 51 extending along the second direction Y form a mesh structure for transmitting a first power supply signal in a mesh shape on the display substrate, which may not only effectively reduce resistance of the first power supply line and reduce a voltage drop of the first power supply signal, but also effectively improve uniformity of the first power supply signal in the display substrate, effectively improve display uniformity and improve display quality.

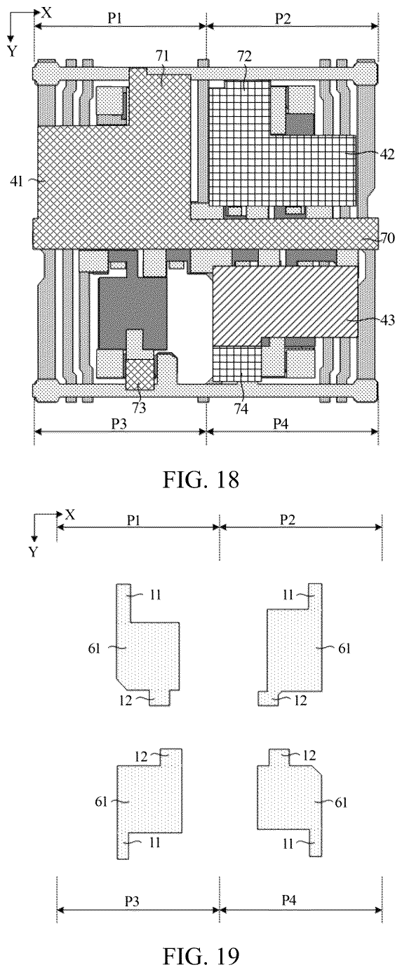

FIG. 18 is a schematic diagram of a structure of a color film structure layer in another display substrate according to an exemplary embodiment of the present disclosure, illustrating a structure of a color filter layer in one repetition unit (four sub-pixels) of a bottom emission display substrate. As shown in FIG. 18, a main body structure of the color film structure layer in the display substrate of the embodiment is substantially the same as that of the foregoing embodiments, except that second transistors T2 of a second sub-pixel P2and a fourth sub-pixel P4 are shielded by a blue color film layer.

In an exemplary implementation mode, a red color film layer may include a red filter 41, a shielding strip 70, a first shielding block 71, and a third shielding block 73. The blue color film layer may include a blue filter 42, a second shielding block 72, and a fourth shielding block 74. A green color film layer may include a green filter 43. Positions of the above patterns are substantially the same as those of the foregoing embodiments.

In an exemplary implementation mode, taking four sub-pixels (a first sub-pixel P1, a second sub-pixel P2, a third sub-pixel P3, and a fourth sub-pixel P4) of one repetition unit as an example, a preparation process of the display substrate of the embodiment may include following operations.

(201) A pattern of a first conductive layer is formed. In an exemplary implementation mode, forming the pattern of the first conductive layer includes: depositing a first conductive thin film on a base substrate, patterning the first conductive thin film through a patterning process, to form the pattern of the first conductive layer on the base substrate, as shown in FIG. 19.

In an exemplary implementation mode, the first conductive layer of each sub-pixel in the display substrate may include at least a first connection electrode 11, a second connection electrode 12, and a first electrode plate 61, and positions, shapes, and functions of the above patterns are substantially the same as those of the foregoing embodiments, except that in a first pixel column, an edge of the first connection electrode 11 on a side away from a second pixel column and an edge of the first electrode plate 61 on a side away from the second pixel column may be substantially flush. In the second pixel column, an edge of the first connection electrode 11 on a side away from the first pixel column and an edge of the first electrode plate 61 on a side away from the first pixel column may be substantially flush.

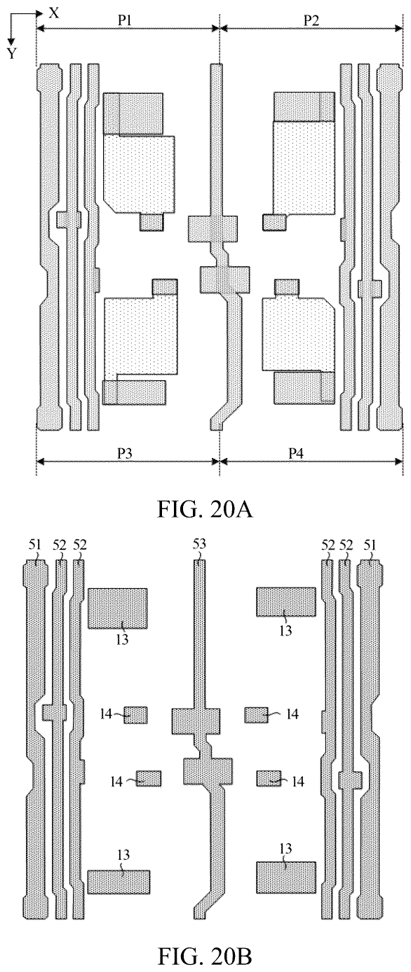

(202) A pattern of a second conductive layer is formed. In an exemplary implementation mode, forming the pattern of the second conductive layer may include: depositing a second conductive thin film on the base substrate on which the aforementioned pattern is formed, and patterning the second conductive thin film through a patterning process to form the second conductive layer, as shown in FIG. 20A and FIG. 20B, wherein FIG. 20B is a schematic diagram of the second conductive layer in FIG. 20A.

In an exemplary implementation mode, the second conductive layer of each repetition unit in the display substrate may include at least two first power supply lines 51, four data signal lines 52, and one compensation signal line 53, and positions, shapes, and functions of the above patterns are substantially the same as those of the foregoing embodiments.

In an exemplary implementation mode, the second conductive layer of each sub-pixel in the display substrate may include at least a third connection electrode 13 and a fourth connection electrode 14, and positions, shapes, and functions of the above patterns are substantially the same as those of the foregoing embodiments, except that a lapping position of the third connection electrode 13 and the first connection electrode 11 is different since a position of the first connection electrode 11 is different.

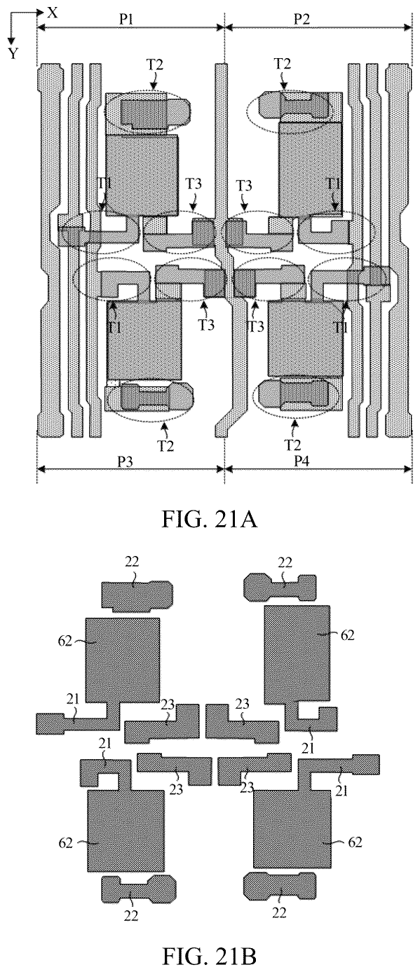

(203) A pattern of a semiconductor layer is formed. In an exemplary implementation mode, forming the pattern of the semiconductor layer may include: depositing a first insulation thin film and a semiconductor thin film sequentially on the base substrate on which the aforementioned patterns are formed, and patterning the semiconductor thin film through a patterning process to form a first insulation layer that covers the first conductive layer and the second conductive layer, and the semiconductor layer disposed on the first insulation layer, as shown in FIG. 21A and FIG. 21B, wherein FIG. 21B is a schematic diagram of the semiconductor layer in FIG. 21A.

In an exemplary implementation mode, the semiconductor layer of each sub-pixel in the display substrate may include at least a first active layer 21, a second active layer 22, a third active layer 23, and a second electrode plate 62. Positions, shapes, and functions of the above patterns are substantially the same as those of the foregoing embodiments, except that second active layers 22 of four sub-pixels are disposed separately, i.e., there is no connection between a second active layer 22 of a first sub-pixel P1 and a second active layer 22 of a second sub-pixel P2, and there is no connection between a second active layer 22 of a third sub-pixel P3 and a second active layer 22 of a fourth sub-pixel P4.

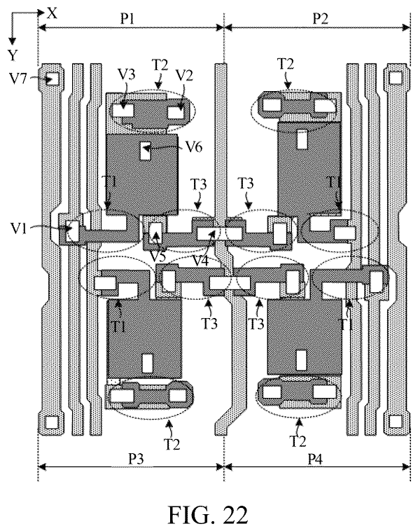

(204) A pattern of a second insulation layer is formed. In an exemplary implementation mode, forming the pattern of the second insulation layer may include: depositing a second insulation thin film on the base substrate on which the aforementioned patterns are formed, patterning the second insulation thin film through a patterning process to form the pattern of the second insulation layer that covers the semiconductor layer, wherein a plurality of vias are disposed on the second insulation layer, as shown in FIG. 22.

In an exemplary implementation mode, a plurality of vias of each sub-pixel in the display substrate include at least a first via V1, a second via V2, a third via V3, a fourth via V4, a fifth via V5, a sixth via V6, and a seventh via V7, positions, shapes, and functions of the above vias are substantially the same as those of the foregoing embodiments, except that the fourth via V4 includes two shallow half holes and a deep hole between the two shallow half holes, and the seventh via V7 is configured such that a power supply connection line to be formed subsequently is connected with a first power supply line 51 through the via.

In an exemplary implementation mode, the fourth via V4 includes two shallow half holes and a deep hole located between the two shallow half holes. A second insulation layer in the two shallow half holes is etched away to expose a surface of a first region of a third active layer 23 in a first pixel column and a surface of a first region of a third active layer 23 in a second pixel column, respectively. A first insulation layer and the second insulation layer in the deep hole are etched away to expose a surface of the compensation signal line 53, so that a via of an adapter structure composed of the two shallow half holes and the deep hole simultaneously exposes the compensation signal line 53, the first region of the third active layer 23 in the first pixel column, and the first region of the third active layer 23 in the second pixel column. The fourth via V4 is configured such that a ninth connection electrode to be formed subsequently is simultaneously connected with the compensation signal lines 53, the first region of the third active layer 23 in the pixel column, and the first region of the third active layer 23 in the second pixel column through the via.

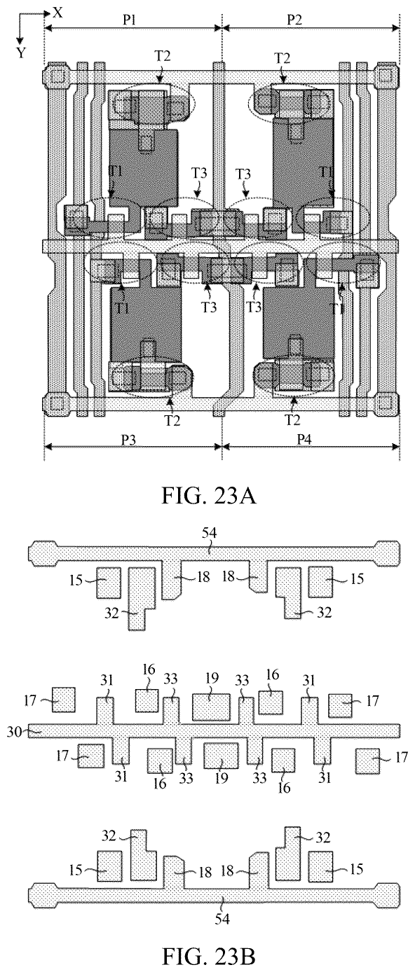

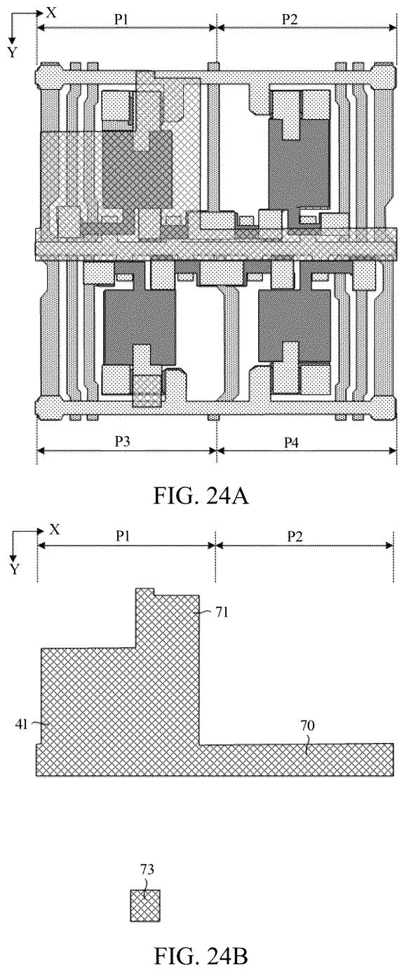

(205) A pattern of a third conductive layer is formed. In an exemplary implementation mode, forming the pattern of the third conductive layer may include: depositing a third conductive thin film on the base substrate on which the aforementioned patterns are formed, patterning the third conductive thin film through a patterning process to form the pattern of the third conductive layer on the second insulation layer, as shown in FIG. 23A and FIG. 23B, wherein FIG. 23B is a schematic diagram of the third conductive layer in FIG. 23A.

In an exemplary implementation mode, the third conductive layer of one repetition unit in the display substrate may include one scan signal line 30 and a power supply connection line 54. The third conductive layer of each sub-pixel in the display substrate may include at least a fifth connection electrode 15, a sixth connection electrode 16, a seventh connection electrode 17, an eighth connection electrode 18, a ninth connection electrode 19, a first gate electrode 31, a second gate electrode 32, and a third gate electrode 33. Positions, shapes, and functions of the above patterns are substantially the same as those of the foregoing embodiments, except that the eighth connection electrode 18 and the ninth connection electrode 19 are different.

In an exemplary implementation mode, the eighth connection electrode 18 may have a strip shape extending along the second direction Y. A first end of the eighth connection electrode 18 is connected with the power supply connection line 54. A second end of the eighth connection electrode 18 extends along a direction towards the second electrode plate 62, and is connected with a first region of the second active layer 22 through the second via V2.

In an exemplary implementation mode, the ninth connection electrode 19 may have a rectangular shape and may be disposed between third gate electrodes 33 of two sub-pixels adjacent to each other in the first direction X. The ninth connection electrode 19 is simultaneously connected with a compensation signal line 53, a first region of a third active layer 23 in a first pixel column, and a first region of a third active layer 23 in a second pixel column through the fourth via V4, thereby achieving that the compensation signal line 53 writes a compensation signal into a first electrode of a third transistor T3.

In an exemplary implementation mode, the power supply connection line 54 may have a line shape extending along the first direction X and may be disposed in a first pixel row and a second pixel row, respectively, and the power supply connection line 54 is connected with the first power supply line 51 through the seventh via V7. Since the power supply connection line 54 is connected with the eighth connection electrode 18, and the eighth connection electrode 18 is connected with the first region of the second active layer 22, it is achieved that the first power supply line 51 writes a first power supply signal into a first electrode of a second transistor T2.

In an exemplary implementation mode, since the power supply connection line 54 is connected, the power supply connection line 54 extending along the first direction X and the first power supply line 51 extending along the second direction Y form a mesh structure for transmitting a first power supply signal in a mesh shape on the display substrate, which not only may effectively reduce resistance of the first power supply line and reduce a voltage drop of the first power supply signal, but also may effectively improve uniformity of the first power supply signal in the display substrate, effectively improve display uniformity, and improve display quality.

(206) Patterns of a third insulation layer and a red color film layer are formed. In an exemplary implementation mode, forming the patterns of the third insulation layer and the red color film layer may include: depositing a third insulation thin film on the base substrate on which the aforementioned patterns is formed, to form the third insulation layer covering the aforementioned patterns. Then, a red color film thin film is coated, and the red color film thin film is patterned through a patterning process to form a pattern of the red color film layer on the planarization layer, as shown in FIGS. 24A and 24B, wherein FIG. 24B is a schematic diagram of the red color film layer in FIG. 24A.

In an exemplary implementation mode, the red color film layer in one repetition unit in the display substrate may include a red filter 41, a shielding strip 70, a first shielding block 71, and a third shielding block 73, and positions, shapes, and functions of the above patterns are substantially the same as those of the foregoing embodiments.

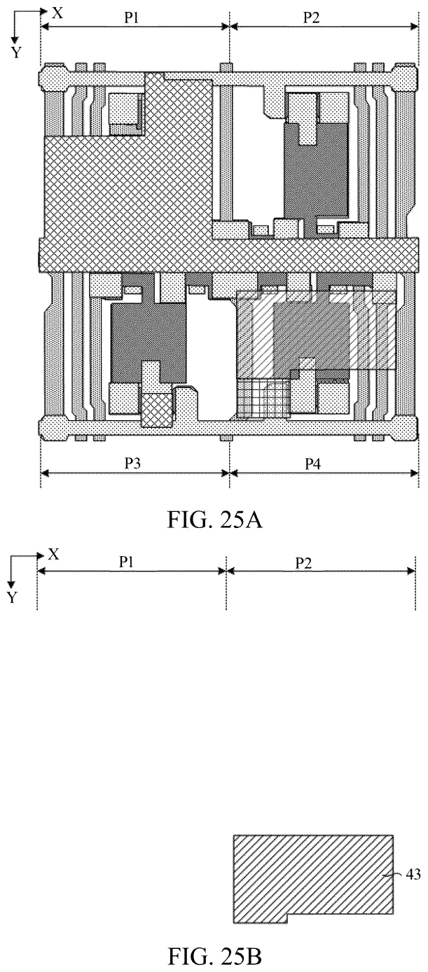

(207) A pattern of a green color film layer is formed. In an exemplary implementation mode, forming the pattern of the green color film layer may include: coating a green color film thin film on the base substrate on which the aforementioned patterns are formed, patterning the green color film thin film through a patterning process, and forming the pattern of the green color film layer on the planarization layer, as shown in FIGS. 25A and 25B, wherein FIG. 25B is a schematic diagram of the green color film layer in FIG. 25A.

In an exemplary implementation mode, the green color film layer in one repetition unit in the display substrate may include a green filter 43, and a position, a shape, and a function of the green filter 43 are substantially the same as those of the foregoing embodiments.

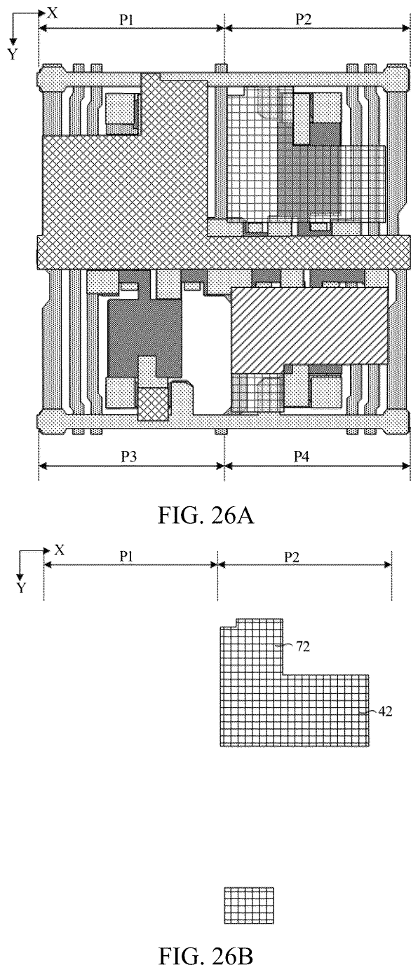

(208) A pattern of a blue color film layer is formed. In an exemplary implementation mode, forming the pattern of the blue color film layer may include: coating a blue color film thin film on the base substrate on which the aforementioned patterns are formed, patterning the blue color film thin film through a patterning process, and forming the pattern of the blue color film layer on the planarization layer, as shown in FIGS. 26A and 26B, wherein FIG. 26B is a schematic diagram of the blue color film layer in FIG. 26A.

In an exemplary implementation mode, the blue color film layer in one repetition unit in the display substrate may include a blue filter 42, a second shielding block 72, and a fourth shielding block 74.

In the exemplary implementation mode, a position, a shape, and a function of the blue filter 42 are substantially the same as those of the foregoing embodiments.

In an exemplary implementation mode, the second shielding block 72 may have a strip shape extending along the first direction X and may be disposed in a second sub-pixel P2, and an orthographic projection of the second shielding block 72 on the base substrate is at least partially overlapped with an orthographic projection of a second transistor T2 in the second sub-pixel P2 on the base substrate, to shield the second transistor T2 in the second sub-pixel P2.

In an exemplary implementation mode, the blue filter 42 and the second shielding block 72 may be of an interconnected integral structure.

In an exemplary implementation mode, the fourth shielding block 74 may have a rectangular shape and may be disposed in a fourth sub-pixel P4, and an orthographic projection of the fourth shielding block 74 on the base substrate is at least partially overlapped with an orthographic projection of a second transistor T2 in the fourth sub-pixel P4 on the base substrate, to shield the second transistor T2 in the fourth sub-pixel P4.

In an exemplary implementation mode, in the present disclosure, the red color film layer is used for shielding second transistors T2 of the first sub-pixel P1 and the third sub-pixel P3, and the blue color film layer is used for shielding second transistors T2 of the second sub-pixel P2 and the fourth sub-pixel P4, which may improve a shielding effect and effectively ensure electrical performance of the second transistors T2.

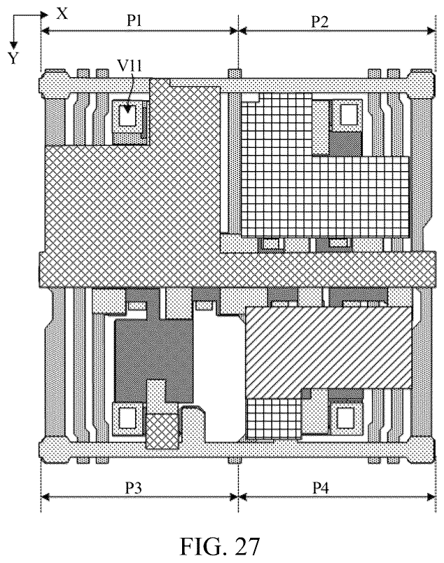

(209) A pattern of a planarization layer is formed. In an exemplary implementation mode, forming the pattern of the planarization layer may include: coating a planarization thin film on the base substrate on which the aforementioned patterns are formed, patterning the planarization thin film and a third insulation thin film through a patterning process, forming the pattern of the planarization layer covering the color film structure layer, wherein the planarization layer is provided with a plurality of vias, as shown in FIG. 27.

In an exemplary implementation mode, a via of each sub-pixel in the display substrate includes at least an eleventh via V11, a position, a shape and a function of the eleventh via V11 are substantially the same as those of the foregoing embodiments.

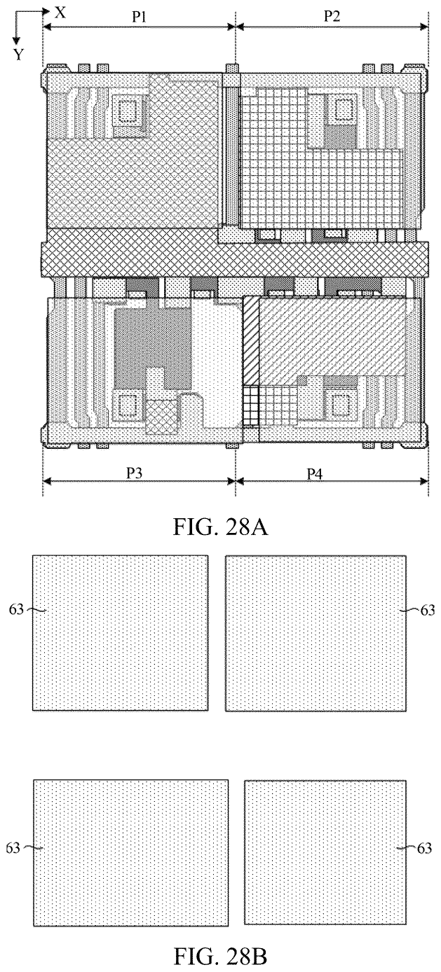

(210) A pattern of a fourth conductive layer is formed. In an exemplary implementation mode, forming the pattern of the fourth conductive layer may include: depositing a fourth conductive thin film on the base substrate on which the aforementioned patterns are formed, patterning the fourth conductive thin film through a patterning process to form the pattern of the fourth conductive layer on a color film layer, as shown in FIG. 28A and FIG. 28B, wherein FIG. 28B is a schematic diagram of the fourth conductive layer in FIG. 28A.

In an exemplary implementation mode, the fourth conductive layer of each sub-pixel in the display substrate may include at least the third electrode plate 63.

In an exemplary implementation mode, a shape of the third electrode plate 63 may have a rectangular shape. Corners of the rectangular shape may be provided with chamfers. An orthographic projection of the third electrode plate 63 on the base substrate is at least partially overlapped with an orthographic projection of the second electrode plate 62 on the base substrate, and the third electrode plate 63 is connected with the fifth connection electrode 15 through the eleventh via V11. The third electrode plate 63 may serve as a transparent upper electrode plate of a transparent storage capacitor, and the third electrode plate 63 and the second electrode plate 62 form a transparent second capacitor. In an exemplary implementation mode, the third electrode plate 63 also serves as an anode of a light emitting device.

In an exemplary implementation mode, four third electrode plates 63 (anodes) in one repetition unit are arranged in a square, an upper left anode is connected with a pixel drive circuit in a first sub-pixel P1, an upper right anode is connected with a pixel drive circuit in a second sub-pixel P2, a lower left anode is connected with a pixel drive circuit in a third sub-pixel P3, and a lower right anode is connected with a pixel drive circuit in a fourth sub-pixel P4. In some possible implementation modes, an arrangement mode of the anodes may be adjusted according to actual needs, which is not specifically limited herein in the present disclosure.

In an exemplary implementation mode, since the third electrode plate 63 is connected with the fifth connection electrode 15, the fifth connection electrode 15 is connected with the third connection electrode 13, the third connection electrode 13 is connected with the first connection electrode 11, and the first connection electrode 11 is connected with the first electrode plate 61, it is achieved that the first electrode plate 61 and the third electrode plate 63 have a potential of a second node in a pixel drive circuit. Since the second electrode plate 62 has a potential of a first node in the pixel drive circuit, the first electrode plate 61 having the potential of the second node and the second electrode plate 62 having the potential of the first node form a first capacitor. The third electrode plate 63 having the potential of the second node and the second electrode plate 62 having the potential of the first node form a second capacitor. And the first capacitor and the second capacitor are connected in parallel, and the first capacitor and the second capacitor in a parallel structure constitute a complete storage capacitor.

In an exemplary implementation mode, since the first electrode plate 61 and the third electrode plate 63 are made of a transparent conductive material and the second electrode plate 62 is made of a transparent metal oxide, the storage capacitor is a transparent capacitor.

In the present disclosure, a first conductive layer of a transparent conductive material, a semiconductor layer of a transparent metal oxide, and a fourth conductive layer of a transparent conductive material are utilized to form a first capacitor and a second capacitor in a parallel structure. The first capacitor and the second capacitor in the parallel structure constitute a complete storage capacitor. On one hand, a capacitance value of the storage capacitor may be effectively increased, and on the other hand,, an area of an electrode plate may be reduced under a condition of ensuring the capacitance value of the storage capacitor, and an occupied area may be effectively reduced.

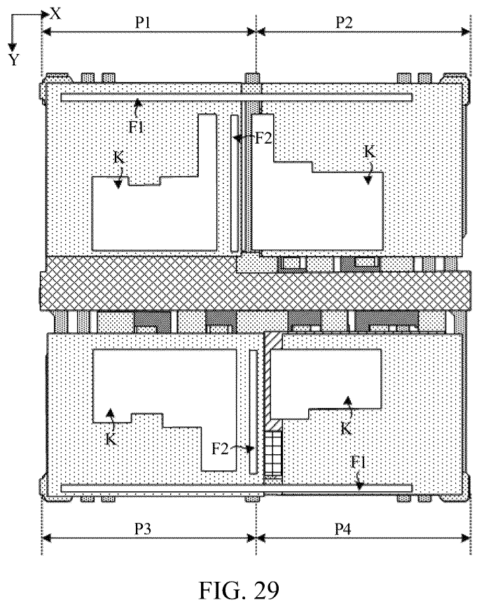

(211) A pixel definition layer is formed. In an exemplary implementation mode, forming a pattern of the pixel definition layer may include: coating a pixel definition thin film on the base substrate on which the aforementioned patterns are formed, patterning the pixel definition thin film through a patterning process, to form the pixel definition layer, as shown in FIG. 29.

In an exemplary implementation mode, a pixel opening K is formed on the pixel definition layer of each sub-pixel in the display substrate, and a position, a shape, and a function of the pixel opening K are substantially the same as those of the foregoing embodiments.

In an exemplary implementation mode, at least one first pixel slot F1 and at least one second pixel slot F2 are also disposed on the pixel definition layer in at least one repetition unit. In an exemplary implementation mode, the first pixel slot F1 may have a strip shape in which a main body portion extends along the first direction X (a pixel row direction), and may be disposed on two sides of the repetition unit in the second direction Y (a pixel column direction). The second pixel slot F2 may have a strip shape in which a main body portion extends along the second direction Y, and may be disposed in a middle of the repetition unit in the first direction X, and located between pixel openings K adjacent to each other in the first direction X. In an exemplary implementation mode, the first pixel slot F1 and the second pixel slot F2 are configured to truncate an organic emitting layer to be formed subsequently, block a lateral propagation path of hole-type carriers, eliminate lateral leakage, and eliminate lateral crosstalk of sub-pixels.

(212) Patterns of an organic emitting layer, a cathode, and an encapsulation layer are formed, which will not be repeated here.

In an exemplary implementation mode, thus, preparation of the display substrate of the embodiment is completed.

The display substrate may include a drive circuit layer disposed on a base substrate, a color film structure layer disposed on a side of the drive circuit layer away from the base substrate, a light emitting structure layer disposed on a side of the color film structure layer away from the base substrate, and an encapsulation layer disposed on a side of the light emitting structure layer away from the base substrate. In a direction perpendicular to the base substrate, the drive circuit layer may include a first conductive layer, a second conductive layer, a first insulation layer, a semiconductor layer, a second insulation layer, a third conductive layer, a third insulation layer, and a planarization layer sequentially disposed on the base substrate. The color film structure layer may include a red filter, a blue filter, a green filter, a shielding strip, and a plurality of shielding blocks. The light emitting structure layer may include an anode, a pixel definition layer, an organic emitting layer, and a cathode. The encapsulation layer may include a first encapsulation layer, a second encapsulation layer, and a third encapsulation layer that are stacked.

In an exemplary implementation mode, the base substrate may be a flexible base substrate, or a rigid base substrate. The rigid base substrate may be made of, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation mode, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the base substrate, and a material of the semiconductor layer may be amorphous silicon (a-si).

In an exemplary implementation mode, the second conductive layer and the third conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, and the third insulation layer may be made of any one or more of Silicon Oxide (SiOx), Silicon Nitride (SiNx), and Silicon Oxynitride (SiON), and may be a single layer, a multi-layer, or a composite layer. The planarization layer may be made of an organic material such as resin.

At present, existing display substrates have problems of complex production processes and high production costs, etc. For example, a preparation process of a drive structure layer in a display substrate requires nine times of patterning (MASK) processes, which not only has a relatively low production efficiency and a relatively high production cost, but also affects a product yield adversely.

An embodiment of the present disclosure provides a display substrate with a bottom emission structure. By disposing structures such as a first power supply line, a data signal line, and a compensation signal line in a second conductive layer, located on a side of a semiconductor layer close to a base substrate, and by disposing structures such as a scan signal line and gate electrodes of a plurality of transistor in a third conductive layer, located on a side of the semiconductor layer away from the base substrate, not only one conductive layer is reduced, but also a patterning process of an adapter via and a patterning process of an adapter conductive layer are reduced, so that a preparation process of a drive structure layer only needs six times of patterning processes, times of patterning processes are reduced, a production efficiency is effectively improved, a production cost is effectively reduced, and a product yield is maximally improved.

Pixels of the display substrate according to the embodiment of the present disclosure are arranged in a square manner, which may effectively increase an aperture ratio and an area of a light transmission region, and is more suitable for display of a display type.

In the display substrate according to the embodiment of the present disclosure, for a 3T1C pixel drive circuit, one scan signal line is adopted, and one scan signal line is connected with a first transistor and a third transistor in the pixel drive circuit. By reducing a quantity of scan signal lines, a structure of the pixel drive circuit may be simplified, an occupied area of the pixel drive circuit may be reduced, and high-resolution display may be realized; moreover, a light transmission area of a light transmission region may be effectively increased, and a space proportion of the light transmission region may be increased, which is beneficial to achievement of high-transparency display. In addition, since one repetition unit only needs to be driven by one scan signal line, a quantity of corresponding gate drive circuits (GOA) and clock signal lines (CLK) may be reduced by multiple times, areas occupied by the gate drive circuits and clock signal lines are effectively reduced, which is beneficial to achieving a narrow bezel, and improving product advantages.

In the display substrate according to the embodiment of the present disclosure, the first conductive layer, the semiconductor layer, and the fourth conductive layer are utilized to form the first capacitor and the second capacitor of a sandwich structure and the first capacitor and the second capacitor in a parallel structure form a storage capacitor, on one hand, a capacitance value of the storage capacitor may be effectively increased, and on the other hand,, an area of an electrode plate may be reduced under a condition of ensuring the capacitance value of the storage capacitor, an occupied area of a pixel drive circuit may be effectively reduced, which is beneficial to achieving high-resolution display.

In the display substrate according to the exemplary embodiment of the present disclosure, a transparent storage capacitor is composed of a transparent conductive layer and a transparent semiconductor layer, so that light may be emitted through the transparent storage capacitor, thus the storage capacitor may be disposed in a pixel opening, and not only a capacitance amount of the storage capacitor may be effectively increased, but also a pixel aperture ratio may be effectively increased.

In the display substrate according to the exemplary embodiment of the present disclosure, a pixel aperture ratio may be effectively increased and a display effect may be improved by adopting a first power supply line structure with a non-mesh structure.

In the display substrate according to the exemplary embodiment of the present disclosure, a first power supply line and a power supply connection line are adopted to form a mesh structure for transmitting a first power supply signal in a mesh shape, which may not only effectively reduce resistance of the first power supply line and reduce a voltage drop of the first power supply signal, but also effectively improve uniformity of the first power supply signal in the display substrate, effectively improve display uniformity, and improve display quality.

The preparation process in the present disclosure may be compatible well with an existing preparation process, is simple in process implementation, is easy to implement, and has a high production efficiency, a low production cost, and a high yield.

A structure shown in the present disclosure and a preparation process thereof are merely exemplary description. In an exemplary implementation mode, a corresponding structure may be changed and patterning processes may be added or reduced according to actual needs, which is not limited here in the present disclosure.

In an exemplary implementation mode, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

An exemplary embodiment according to the present disclosure also provides a preparation method of a display substrate, the display substrate includes a plurality of repetition units, at least one repetition unit includes a plurality of sub-pixels forming at least two pixel rows and two pixel columns, at least one sub-pixel includes a pixel drive circuit connected with a scan signal line, a first power supply line, a data signal line, and a compensation signal line, respectively, wherein the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; the preparation method includes: forming a semiconductor layer and a plurality of conductive layers on a base substrate, wherein the first power supply line, the data signal line, and the compensation signal line are disposed on a side of the semiconductor layer close to the base substrate, and the scan signal line is disposed on a side of the semiconductor layer away from the base substrate.

In an exemplary implementation mode, the forming the semiconductor layer and the plurality of conductive layers on the base substrate may include: forming a first conductive layer on the base substrate and a second conductive layer disposed on a side of the first conductive layer away from the base substrate, wherein the second conductive layer includes at least the first power supply line, the data signal line, and the compensation signal line; forming a first insulation layer covering the second conductive layer and the semiconductor layer disposed on a side of the first insulation layer away from the base substrate; forming a second insulation layer covering the semiconductor layer and a third conductive layer disposed on a side of the second insulation layer away from the base substrate, wherein the third conductive layer includes at least the scan signal line.

In an exemplary implementation mode, the third conductive layer further includes a plurality of connection electrodes, at least one connection electrode is simultaneously connected with the second conductive layer and the semiconductor layer through a via of an adapter structure, the via of the adapter structure includes at least two half holes, the first insulation layer and the second insulation layer in one half hole are removed to expose a surface of the second conductive layer, and the second insulation layer in the other half hole is removed to expose a surface of the semiconductor layer.

The present disclosure also provides a display apparatus which includes the display substrate according to the aforementioned embodiments. The display apparatus may be any product or component with a display function, such as a mobile phone, a tablet computer, a television, a display, a laptop computer, a digital photo frame, and a navigator.

Although implementation modes disclosed in the present disclosure are described as above, the described contents are only implementation modes which are used for facilitating understanding of the present disclosure, but are not intended to limit the present disclosure. Any skilled person in the art to which the present disclosure pertains may make any modification and variation in a form and details of implementation without departing from the spirit and scope of the present disclosure. However, the patent protection scope of the present disclosure should be subject to the scope defined in the appended claims.

1. A display substrate, comprising a plurality of repetition units, wherein at least one repetition unit comprises a plurality of sub-pixels forming at least two pixel rows and two pixel columns, at least one sub-pixel comprises a pixel drive circuit connected with a scan signal line, a first power supply line, a data signal line, and a compensation signal line, respectively, the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; in a direction perpendicular to the display substrate, the display substrate comprises at least a semiconductor layer and a plurality of conductive layers disposed on a base substrate, the first power supply line, the data signal line, and the compensation signal line are disposed on a side of the semiconductor layer close to the base substrate, and the scan signal line is disposed on a side of the semiconductor layer away from the base substrate.

2. The display substrate according to claim 1, wherein in the direction perpendicular to the display substrate, the display substrate comprises at least a first conductive layer, a second conductive layer, a first insulation layer, a semiconductor layer, a second insulation layer, and a third conductive layer disposed on the base substrate and sequentially disposed along a direction away from the base substrate, wherein the first power supply line, the data signal line, and the compensation signal line are disposed in the second conductive layer, and the scan signal line is disposed in the third conductive layer.

3. The display substrate according to claim 2, wherein the third conductive layer further comprises a plurality of connection electrodes, at least one connection electrode is simultaneously connected with the second conductive layer and the semiconductor layer through a via of an adapter structure, the via of the adapter structure comprises at least two half holes, the first insulation layer and the second insulation layer in one half hole are removed to expose a surface of the second conductive layer, and the second insulation layer in the other half hole is removed to expose a surface of the semiconductor layer.

4. The display substrate according to claim 1, wherein the at least one repetition unit further comprises a power supply connection line, the power supply connection line is in a shape of a line extending along a pixel row direction, the first power supply line is in a shape of a line extending along a pixel column direction, and the power supply connection line is connected with the first power supply line to form a mesh structure for transmitting a first power supply signal in a mesh shape.

5. The display substrate according to claim 4, wherein the power supply connection line and the first power supply line are disposed in different conductive layers, and the power supply connection line is connected with the first power supply line through a via.

6. The display substrate according to claim 1, wherein the pixel drive circuit comprises at least a first transistor, a second transistor, a third transistor, and a storage capacitor, wherein a first electrode of the first transistor is connected with the data signal line, a second electrode of the first transistor is connected with a gate electrode of the second transistor and a first end of the storage capacitor respectively, a first electrode of the second transistor is connected with the first power supply line, a second electrode of the second transistor is connected with a second electrode of the third transistor and a second end of the storage capacitor respectively, and a first electrode of the third transistor is connected with the compensation signal line; in a pixel drive circuit of at least one sub-pixel, a gate electrode of the first transistor and a gate electrode of the third transistor are connected with a same scan signal line.

7. The display substrate according to claim 6, wherein in a plurality of pixel drive circuits of at least one pixel row, gate electrodes of a plurality of first transistors and gate electrodes of a plurality of third transistors are connected with a same scan signal line;
or,
in a plurality of pixel drive circuits of at least one repetition unit, gate electrodes of a plurality of first transistors and gate electrodes of a plurality of third transistors are connected with a same scan signal line.

8. (canceled)

9. The display substrate according to claim 6, wherein the scan signal line, the gate electrode of the first transistor, the gate electrode of the second transistor, and the gate electrode of the third transistor are disposed in a same layer.

10. The display substrate according to claim 6, wherein in at least one repetition unit, gate electrodes of a plurality of first transistors and gate electrodes of a plurality of third transistors of adjacent pixel rows are connected with a same scan signal line.

11. The display substrate according to claim 10, wherein the plurality of repetition units comprise an (n−1)-th repetition unit row, an n-th repetition unit row, and an (n+1)-th repetition unit row, wherein n is a positive integer greater than 1, the n-th repetition unit row comprises a first pixel row and a second pixel row, the first pixel row is located on a side of the second pixel row close to the (n−1)-th repetition unit row, the second pixel row is located on a side of the first pixel row close to the (n+1)-th repetition unit row; a first gate electrode and a third gate electrode comprised in the first pixel row in the n-th repetition unit row are all located on a side of the scan signal line close to the (n−1)-th repetition unit row, and a first gate electrode and a third gate electrode comprised in the second pixel row in the n-th repetition unit row are all located on a side of the scan signal line close to the (n+1)-th repetition unit row.

12. The display substrate according to claim 6, wherein the first end of the storage capacitor comprises a first electrode plate and a third electrode plate, and the second end of the storage capacitor comprises a second electrode plate, an orthographic projection of the second electrode plate on the base substrate is at least partially overlapped with an orthographic projection of the first electrode plate on a plane of the display substrate, the first electrode plate and the second electrode plate form a first capacitor, an orthographic projection of the second electrode plate on the plane of the display substrate is at least partially overlapped with an orthographic projection of the third electrode plate on the plane of the display substrate, the third electrode plate and the second electrode plate form a second capacitor, the first electrode plate is respectively connected with the third electrode plate, the second electrode of the first transistor, and the gate electrode of the second transistor, the second electrode plate is respectively connected with the second electrode of the second transistor and the second electrode of the third transistor, and the first capacitor and the second capacitor construct a storage capacitor with a parallel structure.

13. The display substrate according to claim 12, wherein in the direction perpendicular to the display substrate, the display substrate comprises a drive circuit layer disposed on the base substrate, a color film structure layer disposed on a side of the drive circuit layer away from the base substrate, and a light emitting structure layer disposed on a side of the color film structure layer away from the base substrate, the drive circuit layer comprises at least a first conductive layer, a second conductive layer, a semiconductor layer, and a third conductive layer sequentially disposed along a direction away from the base substrate, the light emitting structure layer comprises at least a fourth conductive layer and a pixel definition layer sequentially disposed along the direction away from the base substrate; in at least one sub-pixel, the first electrode plate is disposed in the first conductive layer, the second electrode plate is disposed in the semiconductor layer, the third electrode plate is disposed in the fourth conductive layer, and the third electrode plate is connected with the first electrode plate through a via.

14. The display substrate according to claim 13, wherein a plurality of sub-pixels in at least one repetition unit comprises a first sub-pixel, a second sub-pixel, a third sub-pixel, and a fourth sub-pixel, the first sub-pixel and the second sub-pixel form a first pixel row, the third sub-pixel and the fourth sub-pixel form a second pixel row, the first sub-pixel and the third sub-pixel form a first pixel column, and the second sub-pixel and the fourth sub-pixel form a second pixel column; the color film structure layer comprises at least a red color film layer, a blue color film layer, and a green color film layer, wherein the red color film layer comprises at least a red filter disposed in the first sub-pixel, the blue color film layer comprises at least a blue filter disposed in the second sub-pixel, and the green color film layer comprises at least a green filter disposed in the fourth sub-pixel.

15. The display substrate according to claim 14, wherein the red color film layer further comprises a shielding strip, a first shielding block, a second shielding block, a third shielding block, and a fourth shielding block; an orthographic projection of the shielding strip on the base substrate is at least partially overlapped with an orthographic projection of the scan signal line on the base substrate, an orthographic projection of the first shielding block on the base substrate is at least partially overlapped with an orthographic projection of a second transistor in the first sub-pixel on the base substrate, an orthographic projection of the second shielding block on the base substrate is at least partially overlapped with an orthographic projection of a second transistor in the second sub-pixel on the base substrate, an orthographic projection of the third shielding block on the base substrate is at least partially overlapped with an orthographic projection of a second transistor in the third sub-pixel on the base substrate, and an orthographic projection of the fourth shielding block on the base substrate is at least partially overlapped with an orthographic projection of a second transistor in the fourth sub-pixel on the base substrate.

16. The display substrate according to claim 14, wherein the red color film layer further comprises a shielding strip, a first shielding block, and a third shielding block, and the blue color film layer further comprises a second shielding block and a fourth shielding block; an orthographic projection of the shielding strip on the base substrate is at least partially overlapped with an orthographic projection of the scan signal line on the base substrate, an orthographic projection of the first shielding block on the base substrate is at least partially overlapped with an orthographic projection of a second transistor in the first sub-pixel on the base substrate, an orthographic projection of the second shielding block on the base substrate is at least partially overlapped with an orthographic projection of a second transistor in the second sub-pixel on the base substrate, an orthographic projection of the third shielding block on the base substrate is at least partially overlapped with an orthographic projection of a second transistor in the third sub-pixel on the base substrate, and an orthographic projection of the fourth shielding block on the base substrate is at least partially overlapped with an orthographic projection of a second transistor in the fourth sub-pixel on the base substrate.

17. The display substrate according to claim 13, wherein in at least one sub-pixel, the fourth conductive layer comprises at least the third electrode plate, and a pixel opening exposing the third electrode plate is disposed on the pixel definition layer; in at least one repetition unit, at least one pixel slot is disposed on the pixel definition layer, the pixel slot comprises any one or more of: a first pixel slot extending along a pixel row direction, and a second pixel slot extending along a pixel column direction.

18. A display apparatus, wherein the display apparatus comprises a display substrate according to claim 1.

19. A preparation method of a display substrate, wherein the display substrate comprises a plurality of repetition units, at least one repetition unit comprises a plurality of sub-pixels forming at least two pixel rows and two pixel columns, at least one sub-pixel comprises a pixel drive circuit connected with a scan signal line, a first power supply line, a data signal line, and a compensation signal line, respectively, wherein the scan signal line is configured to provide a scan signal to the pixel drive circuit, the first power supply line is configured to provide a power supply signal to the pixel drive circuit, the data signal line is configured to provide a data signal to the pixel drive circuit, and the compensation signal line is configured to provide a compensation signal to the pixel drive circuit; the preparation method comprises:
forming a semiconductor layer and a plurality of conductive layers on a base substrate, wherein the first power supply line, the data signal line, and the compensation signal line are disposed on a side of the semiconductor layer close to the base substrate, and the scan signal line is disposed on a side of the semiconductor layer away from the base substrate.

20. The preparation method of the display substrate according to claim 19, wherein the forming the semiconductor layer and the plurality of conductive layers on the base substrate comprises:
forming a first conductive layer on the base substrate and a second conductive layer disposed on a side of the first conductive layer away from the base substrate, wherein the second conductive layer comprises at least the first power supply line, the data signal line, and the compensation signal line;
forming a first insulation layer covering the second conductive layer and the semiconductor layer disposed on a side of the first insulation layer away from the base substrate; and
forming a second insulation layer covering the semiconductor layer and a third conductive layer disposed on a side of the second insulation layer away from the base substrate, wherein the third conductive layer comprises at least the scan signal line.

21. The preparation method of the display substrate according to claim 20, wherein the third conductive layer further comprises a plurality of connection electrodes, at least one connection electrode is simultaneously connected with the second conductive layer and the semiconductor layer through a via of an adapter structure, the via of the adapter structure comprises at least two half holes, the first insulation layer and the second insulation layer in one half hole are removed to expose a surface of the second conductive layer, and the second insulation layer in the other half hole is removed to expose a surface of the semiconductor layer.
